(19) United States
(12) Patent Application Publication
(10) Pub. No.: US 2026/0269571 A1
(43) Pub. Date: Sep. 10, 2026

(54) SURFACE EMITTING LASER AND RANGING DEVICE

(71) Applicant: Sony Group Corporation, Tokyo (JP)

(72) Inventors: Tomomasa WATANABE, Kanagawa (JP); Mikihiro YOKOZEKI, Kanagawa (JP)

(21) Appl. No.: 18/873,623

(22) PCT Filed: May 17, 2023
(86) PCT No.: PCT/JP2023/018363

§ 371 Date: Dec. 10, 2024

(30) Foreign Application Priority Data
Jun. 20, 2022 (JP) 2022-098874

(51) Int. Cl. H01S 5/183; H01S 5/30; H01S 5/343

(52) U.S. Cl. CPC H01S 5/18369; H01S 5/18311; H01S 5/3095; H01S 5/343

(57) ABSTRACT

Provided is a surface emitting laser capable of obtaining desired characteristics while suppressing occurrence of structural defects.

A surface emitting laser according to the present technology includes a resonator including: a first structure including a substrate and a first reflector stacked on each other; a second structure that includes a second reflector and is disposed on a side of the first structure corresponding to the first reflector; and an intermediate structure that includes an active layer and is disposed between the first and second structures, in which the substrate includes a material having a lattice constant that is greater than a lattice constant of GaAs and less than a lattice constant of AlAs, and the first reflector and the intermediate structure include different material systems. According to the present technology, it is possible to provide a surface emitting laser capable of obtaining desired characteristics while suppressing occurrence of structural defects.

### TECHNICAL FIELD

The technology according to the present disclosure (hereinafter also referred to as “the present technology”) relates to a surface emitting laser and a ranging device.

### BACKGROUND ART

Conventionally, a vertical cavity surface emitting laser (VCSEL) that emits light in a direction perpendicular to a substrate is known.

Among conventional surface emitting lasers, there is a surface emitting laser in which a resonator including a lower reflector, an active layer, and an upper reflector is provided on a substrate (see, for example, Patent Document 1).

Among conventional surface emitting lasers, there is a surface emitting laser that includes a resonator, which includes different multiple material systems and is provided on a substrate, and with which desired characteristics (for example, characteristics having an oscillation wavelength of an eye-safe band, high reflectivity, and high heat dissipation) can be obtained (for example, see Patent Document 2).

### CITATION LIST

### Patent Document

Patent Document 1: Japanese Patent Application Laid-Open No. 2005-159071

Patent Document 2: Japanese Patent Application Laid-Open No. 11-186653

### SUMMARY OF THE INVENTION

### Problems to be Solved by the Invention

For example, with the surface emitting laser described in Patent Document 1, since the resonator includes a single material system, it is difficult to obtain the desired characteristics described above.

For example, with the surface emitting laser described in Patent Document 2, there has been room for improvement regarding suppression of occurrence of structural defects (for example, bonding defects) due to deformation of the substrate and the resonator.

Therefore, a main object of the present technology is to provide a surface emitting laser capable of obtaining desired characteristics while suppressing occurrence of structural defects.

The present technology provides a surface emitting laser including
a resonator including:
a first structure including a substrate and a first reflector stacked on each other;
a second structure that includes a second reflector and is disposed on a side of the first structure corresponding to the first reflector; and
an intermediate structure that includes an active layer and is disposed between the first and second structures, in which
the substrate includes a material having a lattice constant that is greater than a lattice constant of GaAs and less than a lattice constant of AlAs, and
the first reflector and the intermediate structure include different material systems.

The first reflector may include a material system that lattice-matches with GaAs, and the intermediate structure may include a material system that lattice-matches with InP.

The substrate may include Ge.

The first structure and the intermediate structure may be bonded.

A bonding layer may be formed between the first Structure and the intermediate structure.

The intermediate structure may include a tunnel junction layer stacked on the active layer, the intermediate structure may include a confinement portion configured to confine at least a current, and the confinement portion may include a high resistance region or an insulating region that is present in a peripheral portion of at least a part of the intermediate structure in a thickness direction.

The confinement portion may include an ion implantation region.

The confinement portion may include the high resistance region or the insulating region that is present around at least the tunnel junction layer.

The tunnel junction layer may have a mesa shape, and the confinement portion may include the high resistance region that is present around the tunnel junction layer.

The confinement portion may include the insulating region that is present around the tunnel junction layer.

The tunnel junction layer may include an InAlAs layer around which the insulating region is present.

The insulating region may include an oxidized region.

The insulating region may include a void.

The active layer may include a quantum dot active layer.

The confinement portion may be loop-shaped, the substrate may include a through-hole at a position corresponding to a region surrounded by the confinement portion, and the surface emitting laser may be configured to emit light to a back surface side of the substrate.

The tunnel junction layer may be disposed on an opposite side of the active layer from the substrate.

The tunnel junction layer may be disposed on a side of the active layer corresponding to the substrate. The intermediate structure may include multiple semiconductor structures stacked on one another, and each of the multiple semiconductor structures may include the active layer and the tunnel junction layer.

The intermediate structure may include the multiple confinement portions provided in an in-plane direction.

The present technology also provides a ranging device including:
the surface emitting laser described above; and
a light receiving element provided on a substrate of the surface emitting laser.

### BRIEF DESCRIPTION OF DRAWINGS

FIG. 1 is a cross-sectional view of a surface emitting laser according to a first embodiment of the present technology.

FIG. 2 is a plan view of a surface emitting laser according to the first embodiment of the present technology.

FIG. 3 is a flowchart for describing a first example of a method for manufacturing the surface emitting laser of FIG. 1.

FIGS. 4A to 4C are cross-sectional views for each process of the first example of the method for manufacturing the surface emitting laser of FIG. 1.

FIGS. 5A and 5B are cross-sectional views for each process of the first example of the method for manufacturing the surface emitting laser of FIG. 1.

FIGS. 6A and 6B are cross-sectional views for each process of the first example of the method for manufacturing the surface emitting laser of FIG. 1.

FIGS. 7A and 7B are cross-sectional views for each process of the first example of the method for manufacturing the surface emitting laser of FIG. 1.

FIGS. 8A and 8B are cross-sectional views for each process of the first example of the method for manufacturing the surface emitting laser of FIG. 1.

FIGS. 9A and 9B are cross-sectional views for each process of the first example of the method for manufacturing the surface emitting laser of FIG. 1.

FIG. 10 is a cross-sectional view for each process of the first example of the method for manufacturing the surface emitting laser of FIG. 1.

FIG. 11 is a cross-sectional view for each process of the first example of the method for manufacturing the surface emitting laser of FIG. 1.

FIG. 12 is a cross-sectional view for each process of the first example of the method for manufacturing the surface emitting laser of FIG. 1.

FIGS. 13A and 13B are cross-sectional views for each process of the first example of the method for manufacturing the surface emitting laser of FIG. 1.

FIG. 14 is a flowchart for describing a second example of a method for manufacturing the surface emitting laser of FIG. 1.

FIGS. 15A to 15C are cross-sectional views for each process of the second example of the method for manufacturing the surface emitting laser of FIG. 1.

FIGS. 16A and 16B are cross-sectional views for each process of the second example of the method for manufacturing the surface emitting laser of FIG. 1.

FIGS. 17A and 17B are cross-sectional views for each process of the second example of the method for manufacturing the surface emitting laser of FIG. 1.

FIGS. 18A and 18B are cross-sectional views for each process of the second example of the method for manufacturing the surface emitting laser of FIG. 1.

FIGS. 19A and 19B are cross-sectional views for each process of the second example of the method for manufacturing the surface emitting laser of FIG. 1.

FIGS. 20A and 20B are cross-sectional views for each process of the second example of the method for manufacturing the surface emitting laser of FIG. 1.

FIGS. 21A and 21B are cross-sectional views for each process of the second example of the method for manufacturing the surface emitting laser of FIG. 1.

FIGS. 22A and 22B are cross-sectional views for each process of the second example of the method for manufacturing the surface emitting laser of FIG. 1.

FIG. 23 is a cross-sectional view of a surface emitting laser according to a second embodiment of the present technology.

FIG. 24 is a cross-sectional view of a surface emitting laser according to Example 1 of a third embodiment of the present technology.

FIG. 25 is a cross-sectional view of a surface emitting laser according to Example 2 of the third embodiment of the present technology.

FIG. 26 is a cross-sectional view of a surface emitting laser according to Example 3 of the third embodiment of the present technology.

FIG. 27 is a cross-sectional view of a surface emitting laser according to Example 1 of a fourth embodiment of the present technology.

FIG. 28 is a cross-sectional view of a surface emitting laser according to Example 2 of the fourth embodiment of the present technology.

FIG. 29 is a cross-sectional view of a surface emitting laser according to Example 3 of the fourth embodiment of the present technology.

FIG. 30 is a cross-sectional view of a surface emitting laser according to a fifth embodiment of the present technology.

FIG. 31 is a cross-sectional view of a surface emitting laser according to Example 1 of a sixth embodiment of the present technology.

FIG. 32 is a cross-sectional view of a surface emitting laser according to Example 2 of the sixth embodiment of the present technology.

FIG. 33 is a cross-sectional view of a surface emitting laser according to Example 3 of the sixth embodiment of the present technology.

FIG. 34 is a cross-sectional view of a surface emitting laser according to a seventh embodiment of the present technology.

FIG. 35 is a cross-sectional view of a surface emitting laser according to an eighth embodiment of the present technology.

FIG. 36 is a cross-sectional view of a surface emitting laser according to a ninth embodiment of the present technology.

FIG. 37 is a plan view of the surface emitting laser according to the ninth embodiment of the present technology.

FIG. 38 is a cross-sectional view of a ranging device according to a tenth embodiment of the present technology.

FIG. 39 is a cross-sectional view of a surface emitting laser according to an eleventh embodiment of the present technology.

FIG. 40 is a cross-sectional view of a surface emitting laser according to a twelfth embodiment of the present technology.

FIG. 41 is a cross-sectional view of a surface emitting laser according to a thirteenth embodiment of the present technology.

FIG. 42 is a cross-sectional view of a surface emitting laser according to a fourteenth embodiment of the present technology.

FIG. 43 is a cross-sectional view of a surface emitting laser according to a fifteenth embodiment of the present technology.

FIG. 44 is a cross-sectional view of a surface emitting laser according to a sixteenth embodiment of the present technology.

FIG. 45 is a cross-sectional view of a surface emitting laser according to a seventeenth embodiment of the present technology.

FIG. 46 is a diagram for explaining a lattice constant of Ge.

FIG. 47 is a diagram illustrating an application example of the surface emitting laser according to the present technology to a distance measuring device.

FIG. 48 is a block diagram illustrating an example of a schematic configuration of a vehicle control system.

FIG. 49 is an explanatory diagram illustrating an example of installation positions of distance measuring devices.

### MODE FOR CARRYING OUT THE INVENTION

Hereinafter, preferred embodiments of the present technology will be described in detail with reference to the accompanying drawings. Note that, in the present specification and the drawings, components having substantially the same functional configurations are denoted by the same reference signs, and redundant descriptions are omitted. The embodiments to be described below provide representative embodiments of the present technology, and the scope of the present technology is not to be narrowly interpreted according to those embodiments. In the present specification, even in a case where it is described that a surface emitting laser and a ranging device according to the present technology exhibit multiple effects, it is sufficient if the surface emitting laser and the ranging device according to the present technology exhibits at least one effect. The effects described in the present specification are merely examples and are not limited, and other effects may be exerted.

Furthermore, the description will be given in the following order.
0. Introduction
1. Surface emitting laser according to first embodiment of present technology
2. Surface emitting laser according to second embodiment of present technology
3. Surface emitting laser according to third embodiment of present technology
4. Surface emitting laser according to fourth embodiment of present technology
5. Surface emitting laser according to fifth embodiment of present technology
6. Surface emitting laser according to sixth embodiment of present technology
7. Surface emitting laser according to seventh embodiment of present technology
8. Surface emitting laser according to eighth embodiment of present technology
9. Surface emitting laser according to ninth embodiment of present technology
10. Ranging device according to tenth embodiment of present technology
11. Surface emitting laser according to eleventh embodiment of present technology
12. Surface emitting laser according to twelfth embodiment of present technology
13. Surface emitting laser according to thirteenth embodiment of present technology
14. Surface emitting laser according to fourteenth embodiment of present technology
15. Surface emitting laser according to fifteenth embodiment of present technology
16. Surface emitting laser according to sixteenth embodiment of present technology
17. Surface emitting laser according to seventeenth embodiment of present technology
18. Modifications of present technology
19. Application examples to electronic device
20. Example in which surface emitting laser is applied to distance measuring device
21. Example in which distance measuring device is mounted on moving body

### 0. Introduction

In general, with InP-based VCSELs, it is difficult to form a semiconductor distributed Bragg reflector (DBR) having high reflectivity and high thermal conductivity (high heat dissipation). Therefore, a technique is known in which a semiconductor DBR (for example, a GaAs-based semiconductor DBR) is grown on a substrate (for example, a GaAs substrate) made of a material system (for example, a GaAs-based semiconductor) different from the InP-based material, and the semiconductor DBR and the InP-based material are bonded together. However, when the GaAs-based semiconductor DBR is formed on the GaAs substrate, the GaAs substrate and the GaAs-based semiconductor DBR are greatly warped, and there is a possibility that bonding between the GaAs-based semiconductor DBR and the InP-based material is hindered. Therefore, this bonding technique has not been put into practical use because there is a concern about a decrease in yield due to a structural defect (for example, a bonding defect).

On the other hand, although an InP-based VCSEL using a dielectric DBR has been put into practical use, there is a problem where high-temperature operation is difficult because thermal conductivity (heat dissipation) of a dielectric material is poor.

Therefore, after intensive studies, the inventors have developed a surface emitting laser according to the present technology as a surface emitting laser capable of obtaining desired characteristics (for example, characteristics having an oscillation wavelength of an eye-safe band, high reflectivity, and high heat dissipation) while suppressing occurrence of structural defects.

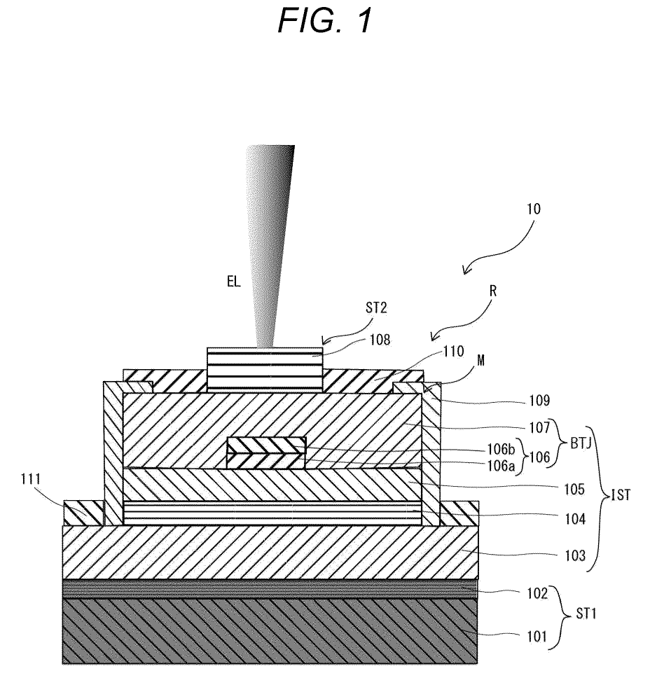

Hereinafter, an embodiment of the surface emitting laser according to the present technology will be described in detail with some embodiments. Hereinafter, for the sake of convenience, the upper part in the cross-sectional view of FIG. 1 and the like will be described as an upper side, and the lower part in the cross-sectional view of FIG. 1 and the like will be described as a lower side.

### 1. Surface Emitting Laser According to First Embodiment of Present Technology

Hereinafter, a surface emitting laser 10 according to a first embodiment of the present technology will be described.

### <<Configuration of Surface Emitting Laser>>

### [Overall Configuration]

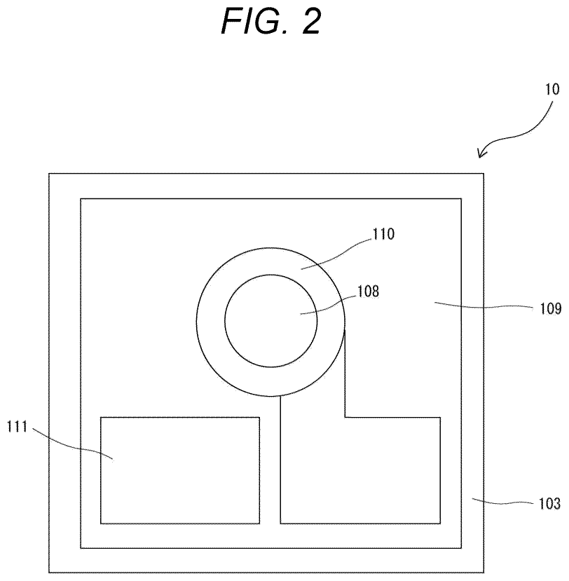

FIG. 1 is a cross-sectional view of a surface emitting laser 10 according to the first embodiment of the present technology. FIG. 2 is a plan view of the surface emitting laser 10 according to the first embodiment of the present technology. The surface emitting laser 10 is a vertical cavity surface emitting laser (VCSEL). As an example, the surface emitting laser 10 can constitute a VCSEL of a long wavelength band (eye-safe band) having an oscillation wavelength λ of, for example, 900 nm or more, or 1.4 μm or more. The oscillation wavelength λ is particularly preferably 1.2 μm or more and 2 μm or less in the eye-safe band. In one example, the surface emitting laser 10 is driven by a laser driver.

As illustrated in FIGS. 1 and 2, in one example, the surface emitting laser 10 includes a resonator R including a first structure ST1, which includes a substrate 101 and a first reflector 102 stacked on each other, a second structure ST2, which includes a second reflector 108 and is disposed on the side corresponding to the first reflector 102 of the first structure ST1, and an intermediate structure IST, which includes an active layer 104 and is disposed between the first and second structures ST1 and ST2. In one example, the second reflector 108 is a reflector on the emission side. The first reflector 102 is also referred to as a lower reflector. The second reflector 108 is also referred to as an upper reflector. Hereinafter, the direction in which the substrate 101, the first reflector 102, and the like are stacked is also referred to as a “layering direction”.

The intermediate structure IST further includes, as an example, a tunnel junction layer 106 stacked on the active layer 104, a first cladding layer 103 disposed on the side of the active layer 104 corresponding to the first structure ST1 (lower side), a second cladding layer 105 disposed between the active layer 104 and the tunnel junction layer 106, and a third cladding layer 107 provided around the tunnel junction layer 106. As an example, the tunnel junction layer 106 is disposed on the opposite side of the active layer 104 from the substrate 101.

As an example, the first structure ST1 and the intermediate structure IST are bonded. As an example, a bonding layer may be formed between the first reflector 102 of the first structure ST1 and the first cladding layer 103 of the intermediate structure IST.

As an example, the intermediate structure IST includes a mesa M, which includes the active layer 104, the second cladding layer 105, the tunnel junction layer 106, and the third cladding layer 107, on the first cladding layer 103. At least a side surface of the mesa M is covered with an insulating film 109.

As an example, the second reflector 108 is provided on the central portion of the top portion of the mesa M (on the central portion of the upper surface of the third cladding layer 107). A loop-shaped (for example, ring-shaped) anode electrode 110 is provided on the peripheral portion of the top portion of the mesa M (on the region around the second reflector 108 on the upper surface of the third cladding layer 107) so as to surround the second reflector 108.

As an example, the cathode electrode 111 is provided on the upper surface of the first cladding layer 103 on the side surface side of the mesa M via the insulating film 109. That is, the surface emitting laser 10 has an intra-cavity structure in which the anode electrode 110 and the cathode electrode 111 are arranged on the same surface side of the resonator R.

The intermediate structure IST includes a confinement portion that confines at least the current. The confinement portion is a high resistance region or an insulating region that is present in the peripheral portion of at least a part in the thickness direction (layering direction) of the intermediate structure IST. More specifically, the confinement portion is a high resistance region or an insulating region that is present around the tunnel junction layer 106. More specifically, the tunnel junction layer 106 is provided in a mesa shape on the second cladding layer 105, and the confinement portion is a high resistance region that is present around the tunnel junction layer 106. Here, the third cladding layer 107 is an embedding layer that fills the periphery of the tunnel junction layer 106, and a region of the third cladding layer 107 surrounding the tunnel junction layer 106 and having a higher resistance than the tunnel junction layer 106 functions as a confinement portion. That is, the tunnel junction layer 106 and the third cladding layer 107 constitute a buried tunnel junction (BTJ). Hereinafter, the tunnel junction layer 106 is also referred to as a “TJ mesa”. In the BTJ, the confinement portion (high resistance region) surrounding the TJ mesa has higher resistance than the TJ mesa, and thus functions as a current confinement portion. In the BTJ, the confinement portion surrounding the TJ mesa also functions as a light confinement portion if the refractive index is lower than that of the TJ mesa.

### [First Structure]

### (Substrate)

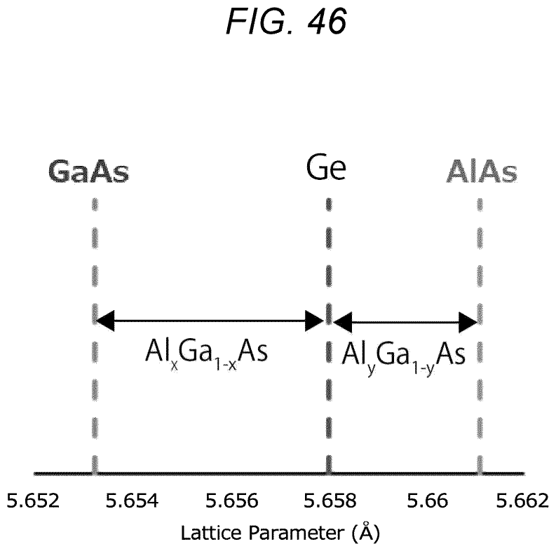

As an example, the substrate 101 includes a material having a lattice constant greater than the lattice constant (5.653) of GaAs and less than the lattice constant (5.661) of AlAs. More specifically, the substrate 101 includes, for example, Ge (lattice constant: 5.658) (see FIG. 46). The substrate 101 is desirably undoped, but may be doped with n-type doping, for example. The dopant (n-type impurity) in this case can be, for example, a group V element (for example, As, Sb, and the like). Since the Ge substrate has low defects and can produce a wafer having a large diameter, the Ge substrate contributes to improvement of reliability and cost reduction.

### (First Reflector)

The first reflector 102 is, for example, a semiconductor multilayer film reflector (semiconductor DBR). The semiconductor multilayer film reflector has a structure in which multiple types (for example, two types) of refractive index layers (semiconductor layers) having different refractive indexes are alternately stacked with an optical thickness of ¼ (λ/4) of an oscillation wavelength λ. Here, the semiconductor multilayer film reflector as the first reflector 102 is desirably undoped, but may be doped with n-type doping, for example. The dopant (n-type impurity) in this case can be, for example, Si, Se, Te, or the like.

As an example, the first reflector 102 is a semiconductor multilayer film DBR of a first material system (GaAs system), which is a material system lattice-matching with GaAs. The first material system (GaAs-based) can also be defined as a material system having a lattice constant within a range of ±0.2% of the lattice constant of GaAs. The GaAs-based semiconductor DBR can obtain high reflectivity and high thermal conductivity as compared with, for example, the InP-based semiconductor DBR with the same number of pairs. As the first material system (GaAs-based), for example, AlₓGa₁₋ₓAs/Al_{y}Ga_{1-y}As (0≤x<1, 0<y≤1, x<y) can be used (see FIG. 46). Here, the first reflector 102 includes, for example, GaAs/AlAs.

In the first structure ST1, the lattice constant (5.658) of Ge constituting the substrate 101 is preferably greater than or equal to the lattice constant of the high refractive index layer (for example, AlₓGa₁₋ₓAs) of the first reflector 102 and less than or equal to the lattice constant of the low refractive index layer (for example, Al_{y}Ga_{1-y}As) of the first reflector 102 (see FIG. 46). That is, the lattice constant of the high refractive index layer (for example, AlₓGa₁₋ₓAs) is preferably less than the lattice constant of Ge, and the lattice constant of the low refractive index layer (for example, Al_{y}Ga_{1-y}As) is preferably greater than the lattice constant of Ge. This is because strains (tensile strain and compressive strain) to be canceled out by each other occur in the high refractive index layer (for example, AlₓGa₁₋ₓAs) and the low refractive index layer (for example, Al_{y}Ga_{1-y}As) alternately stacked on the substrate 101, and a strain compensation relationship is established. Therefore, the value of x is preferably set such that the lattice constant of AlₓGa₁₋ₓAs is less than the lattice constant of Ge, and the value of y is preferably set such that the lattice constant of Al_{y}Ga_{1-y}As exceeds the lattice constant of Ge.

The first structure ST1 may have a buffer layer between the substrate 101 and the second reflector 102.

### [Intermediate Structure]

As an example, the intermediate structure IST includes a material system different from that of the first reflector 102. The intermediate structure IST includes a second material system (InP system) that is a material system lattice-matching with InP. The second material system (InP system) can also be defined as a material system having a lattice constant within a range of ±0.2% of the lattice constant of InP. The second material system (InP-based) includes, for example, InP, AlInAs, AlGaInAs, InGaAsP, and the like.

### (First Cladding Layer)

The first cladding layer 103 includes an n-InP layer, for example. For example, Si can be used as a dopant of the n-InP layer.

### (Active Layer)

As an example, the active layer 104 includes an InP-based compound semiconductor. More specifically, the active layer 104 has a multiple quantum well structure (MQW structure) including AlGaInAs or GaInAsP as an example. Here, the active layer 104 includes, for example, an AlGaInAs/AlGaInAs multiple quantum well layer. In the AlGaInAs/AlGaInAs multiple quantum well layer, the composition and the thickness are designed so that the emission wavelength falls within a range of eye-safe band longer than 1400 nm, for example, but it is preferable to apply opposite strains to the well layer and the barrier layer. In this case, for example, the magnitude of the strain can be about 1%, and the number of wells can be 4 to 8. In the active layer 104, a region corresponding to the tunnel junction layer 106 is a light emitting region. The light emitting region of the active layer 104 is also a heat generation portion.

### (Second Cladding Layer)

The second cladding layer 105 includes a p-InP layer, for example. For example, Mg can be used as a dopant of the p-InP layer.

### (BTJ)

The BTJ includes the tunnel junction layer 106 and the third cladding layer 107 as described above. As described above, the BTJ is disposed on the side of the active layer 104 corresponding to the second reflector 108. That is, the BTJ is located upstream of the active layer 104 along the current path from the anode electrode 110 to the cathode electrode 111.

The third cladding layer 107 includes an n-InP layer, for example. For example, Si can be used as a dopant of the n-InP layer.

The tunnel junction layer 106 (TJ mesa) has much lower resistance (very high carrier conductivity) than the surrounding third cladding layer 107, and serves as a current passage region. As described above, the region of the third cladding layer 107 surrounding the TJ mesa is the confinement portion. The tunnel junction layer 106 is also a heat generation portion. The diameter of the mesa (TJ mesa) of the tunnel junction layer 106 is, for example, several um to several tens um.

The tunnel junction layer 106 includes a p-type semiconductor region 106a and an n-type semiconductor region 106b stacked on each other. Here, the p-type semiconductor region 106a is disposed on a side (lower side) of the n-type semiconductor region 106b adjacent to the active layer 104. The p-type semiconductor region 106a includes, for example, p-type AlInAs (p-AlInAs) doped with carbon (C) at a high concentration. The n-type semiconductor region 106b includes, for example, n-type InP (n-InP) doped with Si, Te, or the like at a high concentration. Note that one of the p-type semiconductor region 106a and the n-type semiconductor region 106b may be made of AlInAs and the other may be made of InP, or both may be made of AlInAs or InP.

### [Second Structure]

### (Second Reflector)

As an example, the second reflector 108 includes a material system different from the intermediate structure IST. The second reflector 108 is, for example, a dielectric multilayer film reflector (dielectric DBR). The dielectric multilayer film reflector has a structure in which multiple types (for example, two types) of refractive index layers (dielectric layers) having different refractive indexes are alternately stacked with an optical thickness of ¼ (λ/4) of an oscillation wavelength λ. The second reflector 108 is preferably made of a material containing, for example, at least one of SiO₂, TiO₂, Ta₂O₅, SiN, a-Si, MgF₂, and CaF₂. The dielectric multilayer film reflector as the second reflector 108 may include, for example, SiO₂/TiO₂, Ta₂O₅/SiO₂, or a-Si/Ta₂O₅. The reflectivity of the second reflector 108 is set slightly lower than that of the first reflector 102. That is, the surface emitting laser 10 is a surface emitting type surface emitting laser 10 that emits laser light as the emitted light EL to the surface side (the side corresponding to the second reflector 108).

### (Insulating Film)

The insulating film 109 is constituted by a dielectric such as SiO₂, SiN, or SiON.

### (Anode Electrode)

The anode electrode 110 includes, for example, Au/Ni/AuGe, Au/Pt/Ti, or the like. The anode electrode 110 is electrically connected to, for example, an anode (positive electrode) of the laser driver. Note that a contact layer (current injection layer) having lower resistance than the third cladding layer 107 may be disposed between the anode electrode 110 and the third cladding layer 107.

### (Cathode Electrode)

The cathode electrode 111 is constituted by, for example, Au/Ni/AuGe, Au/Pt/Ti, or the like. The cathode electrode 111 is electrically connected to, for example, a cathode (negative electrode) of the laser driver.

### <<Operation of Surface Emitting Laser>>

In the surface emitting laser 10, the current flowing from the anode side of the laser driver via the anode electrode 110 is confined by BTJ and injected into the active layer 104 via the second cladding layer 105. At this time, the active layer 104 emits light, and the light reciprocates while being confined by the BTJ and amplified by the active layer 104 between the first and second reflectors 102 and 108, and is emitted as laser light (emitted light EL) from the side corresponding to the second reflector 108 (surface side) when an oscillation condition is satisfied. The current injected into the active layer 104 flows out to the cathode side of the laser driver through the first cladding layer 103 and the cathode electrode 111 in this order.

Part of the heat generated in the tunnel junction layer 106 and the active layer 104 when the surface emitting laser 10 is driven is transmitted to the first reflector 102 via the first cladding layer 103. Part of the heat transferred to the first reflector 102 is released from the side surface of the first reflector 102 to the outside, and the other part is transferred to the first substrate 101 and released from the substrate 101 to the outside. In this case, heat dissipation can be improved as compared with a case where the first reflector 102 is formed of an InP-based semiconductor multilayer film reflector.

### <<First Example of Method for Manufacturing Surface Emitting Laser>>

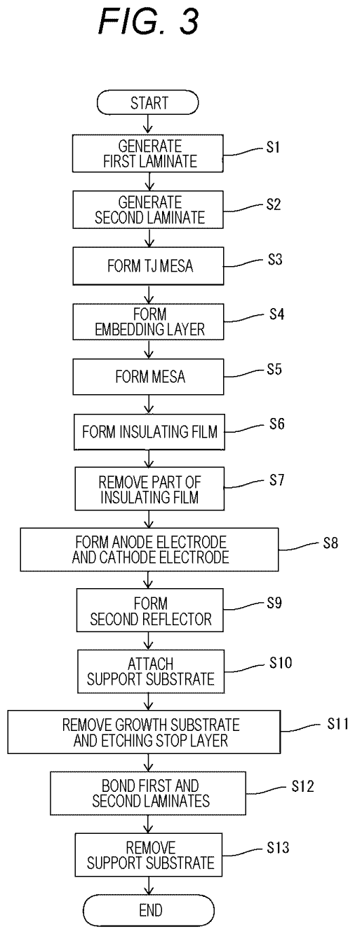

Hereinafter, a first example of a method for manufacturing the surface emitting laser 10 will be described with reference to the flowchart of FIG. 3, for example. Here, as an example, multiple surface emitting lasers 10 are simultaneously generated on one wafer which is the base material of the substrate 101 by a semiconductor manufacturing method using a semiconductor manufacturing apparatus. Next, the multiple surface emitting lasers 10 integrated in series are separated to obtain multiple chip-shaped surface emitting lasers 10 (surface emitting laser chips).

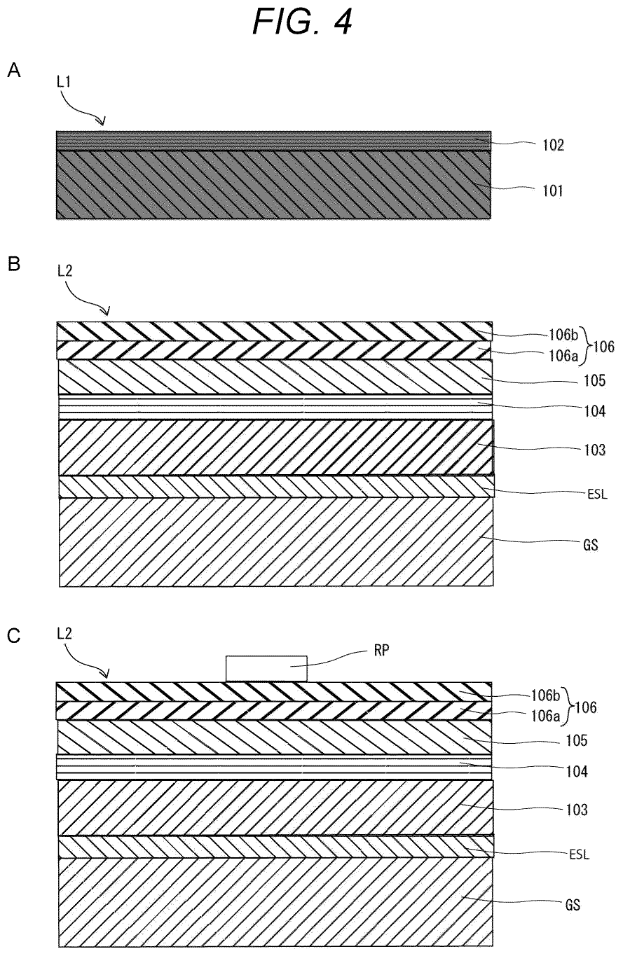

In the first step S1, a first laminate L1 (first structure ST1) is generated (see FIG. 4A). Specifically, as an example, the first reflector 102 (for example, GaAs/AlAs) is epitaxially grown on the substrate 101 (for example, Ge substrate) by a metal organic chemical vapor deposition (MOCVD) method to generate the first laminate L1. At this time, in the first laminate L1, since the lattice constant of Ge constituting the substrate 101 is between the lattice constants of GaAs and AlAs constituting the first reflector 102, strain compensation occurs, and stress is relaxed. As a result, no warpage or substantially no warpage occurs in the substrate 101 and the first reflector 102.

In the next step S2, a second laminate L2 is generated (see FIG. 4B). Specifically, an etching stop layer ESL (for example, an InGaAs layer), the first cladding layer 103 (for example, an n-InP layer), the active layer 104, the second cladding layer 105 (for example, a p-InP layer), and the tunnel junction layer 106 are epitaxially grown in this order on a growth substrate GS (for example, an n-InP substrate) by the MOCVD method to generate a second laminate L2.

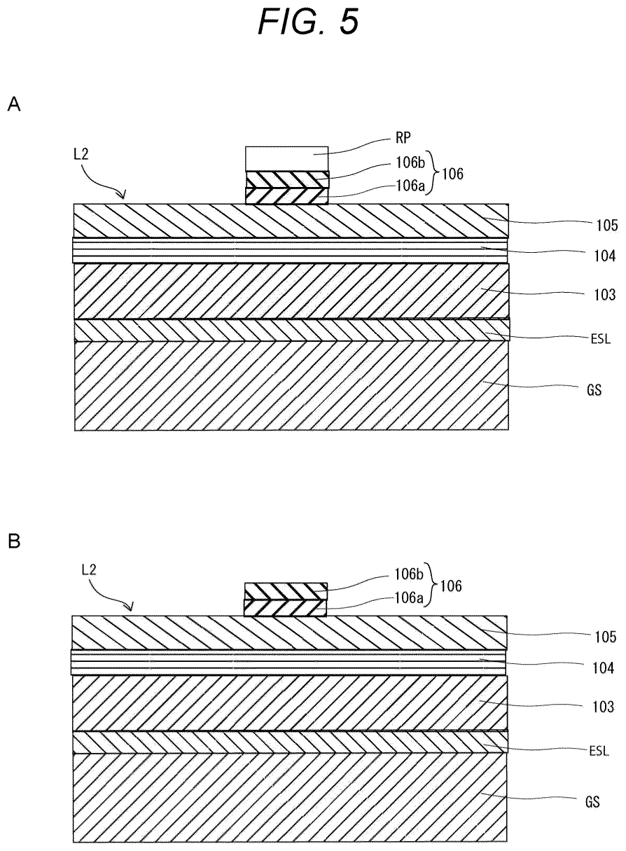

In the next step S3, a TJ mesa is formed. Specifically, first, a resist pattern RP that covers a portion where the TJ mesa is to be formed on the surface of the second laminate L2 corresponding to the tunnel junction layer 106 is formed by photolithography (see FIG. 4C). Next, using the resist pattern RP as a mask, the tunnel junction layer 106 is etched by wet etching using a hydrochloric acid-based etchant to form a TJ mesa (see FIG. 5A). At this time, as an etchant for etching the n-type semiconductor region 106b (for example, the n-InP layer) of the tunnel junction layer 106, for example, a mixed solution of HCl, H₃PO₄, CH₃COOH, H₂O, or the like can be used. As an etchant for etching the p-type semiconductor region 106a (for example, a p-AlInAs layer), for example, a mixed solution of H₃PO₄, H₂O₂, H₂O, or the like can be used. Next, the resist pattern RP is removed by wet etching using an organic solvent or dry etching using a gas such as O₂, CF₄, or H₂ (see FIG. 5B).

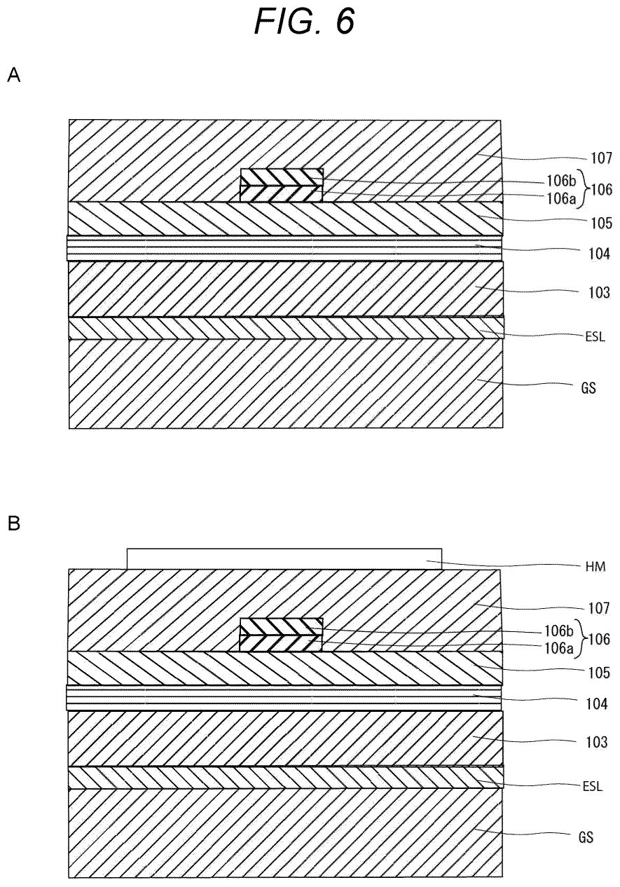

In the next step S4, the third cladding layer 107 as an embedding layer is formed (see FIG. 6A). Specifically, the third cladding layer 107 (for example, an n-InP layer) as an embedding layer is regrown on the second laminate (on the second cladding layer 105) on which the TJ mesa is formed by the MOCVD method. As a result, the TJ mesa is embedded with the third cladding layer 107.

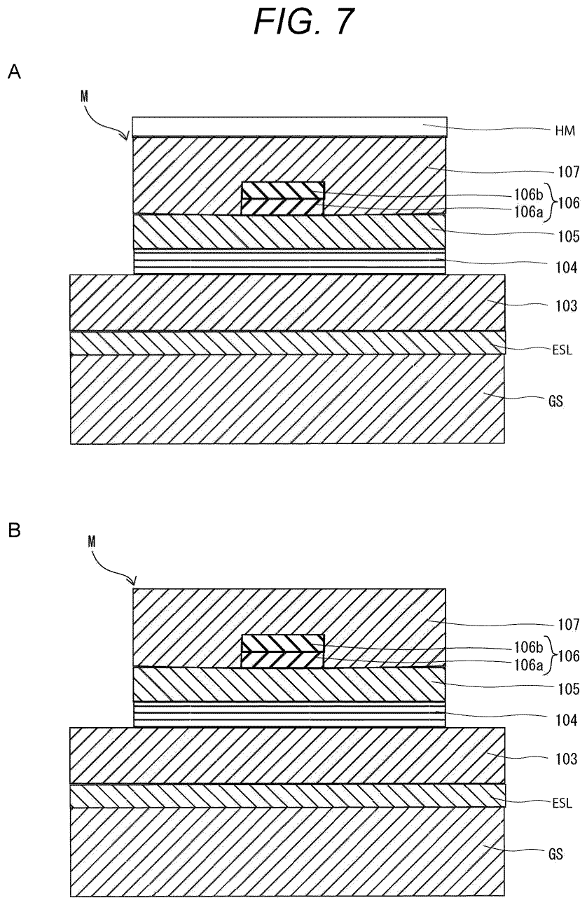

In the next step S5, a mesa M is formed. Specifically, first, a hard mask HM made of an oxide film (for example, a SiO₂ film) covering a portion of the third cladding layer 107 of the second laminate where the mesa M is to be formed is formed by photolithography (see FIG. 6B). At this time, the oxide film as the hard mask HM is formed by a CVD method, a sputtering method, a vapor deposition method, or the like, and the patterning of the oxide film is performed by wet etching using a hydrofluoric acid-based etchant using a resist pattern as a mask. Next, the second laminate is etched by dry etching using a Cl-based gas with the hard mask HM serving as a mask to form a mesa M (see FIG. 7A). At this time, for example, a mixed gas such as Cl₂, BCl₃, SiCl₄, Ar, or O₂ is used. Here, etching is performed at least until the first cladding layer 103 is exposed, but the etching stop layer ESL limits over-etching. Then, the oxide film is removed by wet etching using a hydrofluoric acid-based etchant (see FIG. 7B).

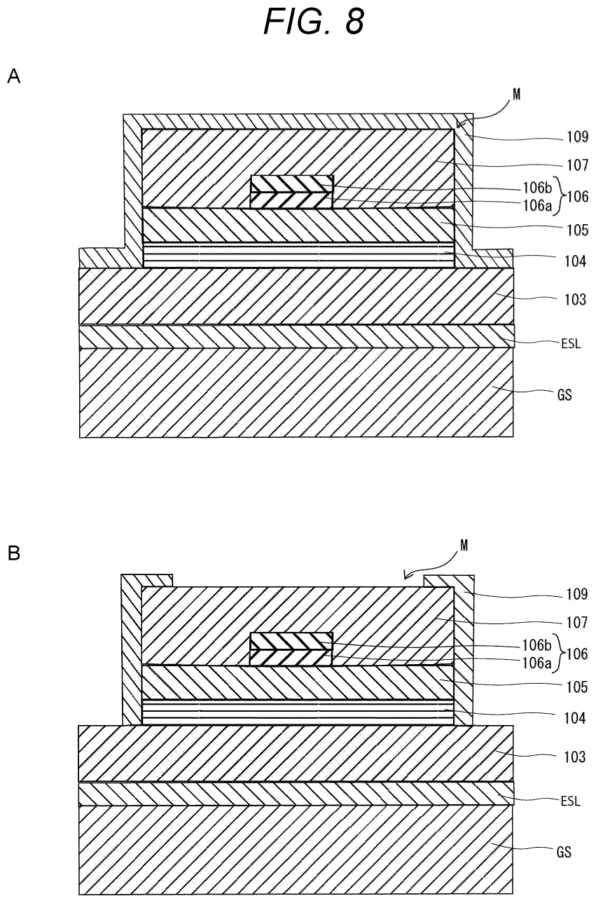

In the next step S6, an insulating film 109 is formed (see FIG. 8A). Specifically, the insulating film 109 is formed on the entire surface of the second laminate.

In the next step S7, a part of the insulating film 109 is removed (see FIG. 8B). Specifically, first, a resist pattern is formed by photolithography to cover a portion of the insulating film 109 other than the portion covering the top of the mesa M and the portion covering the region around the mesa M on the upper surface of the first cladding layer 103. Next, using the resist pattern as a mask, the second laminate is etched by dry etching using, for example, CF₄ gas, thereby exposing the top portion of the mesa M and the region of the upper surface of the first cladding layer 103 around the mesa M.

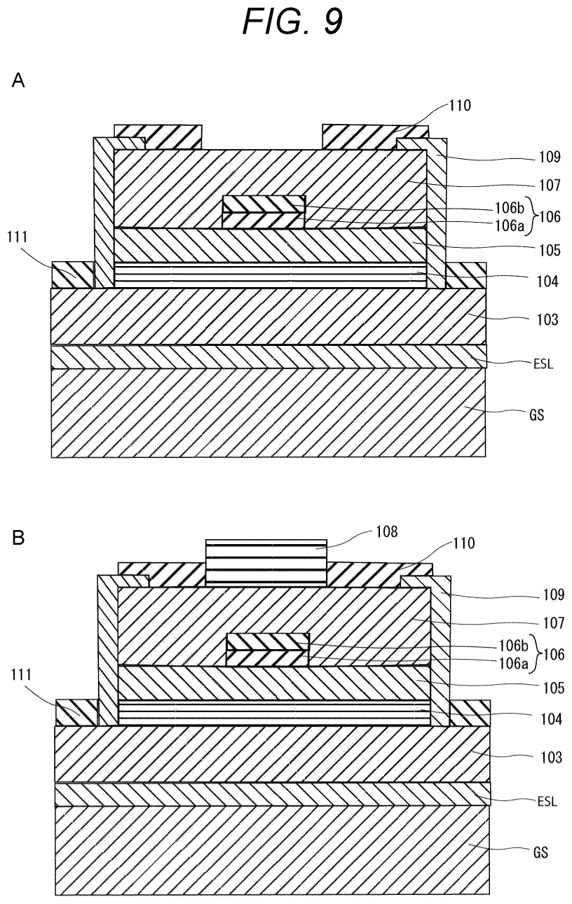

In the next step S8, the anode electrode 110 and the cathode electrode 111 are formed (see FIG. 9A). Specifically, for example, the loop-shaped (for example, ring-shaped) anode electrode 110 is formed on the periphery of the top portion of the mesa M by a lift-off method, and the cathode electrode 111 is formed on the region of the upper surface of the first cladding layer 103 around the mesa M. At this time, the electrode materials of the anode electrode 110 and the cathode electrode 111 are formed by a sputtering method or a vapor deposition method.

In the next step S9, the second reflector 108 is formed (see FIG. 9B). Specifically, first, a dielectric multilayer film to be the material of the second reflector 108 is formed on the entire surface of the second laminate. Next, a resist pattern is formed on the dielectric multilayer film covering the central portion of the top portion of the mesa M by photolithography. Next, by using this resist pattern as a mask, the dielectric multilayer film is etched by dry etching or wet etching. As a result, the second reflector 108 is formed on the central portion of the top portion of the mesa M. Note that the second reflector 108 can also be formed by lift-off, for example.

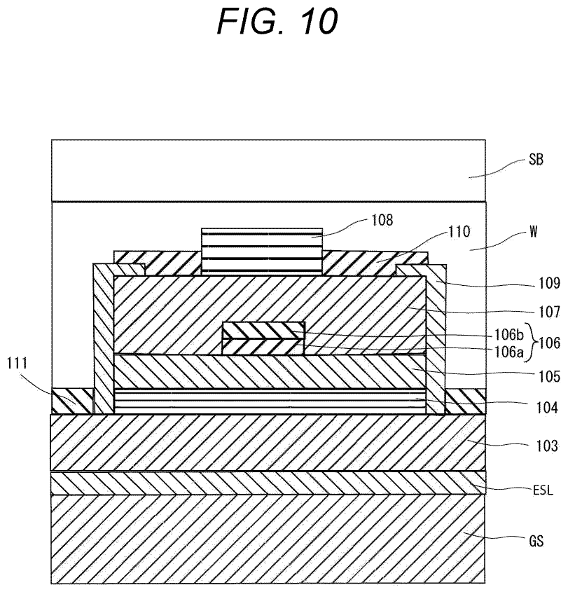

In the next step S10, a support substrate SB is attached to the second laminate (see FIG. 10). Specifically, the support substrate SB is attached to the surface of the second laminate on the side where the mesa M is formed via, for example, wax W. Note that a resin or a tape may be used instead of the wax W for attaching the support substrate SB.

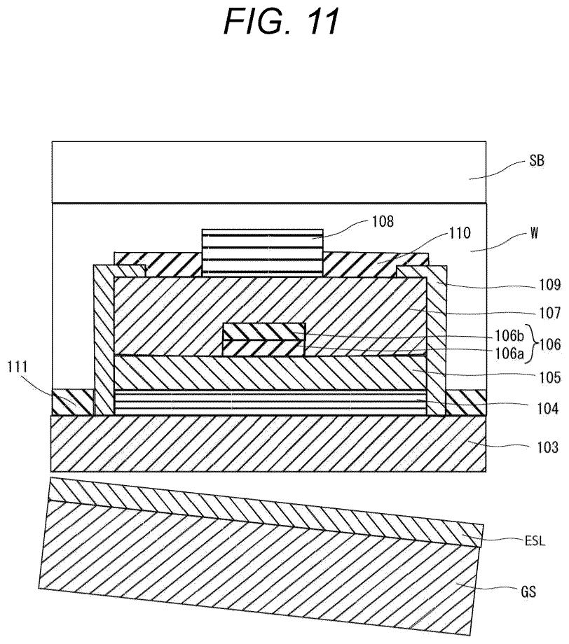

In the next step S11, the growth substrate GS and the etching stop layer ESL are removed (see FIG. 11). Specifically, the back surface of the growth substrate GS is polished with a grinder or a CMP apparatus to thin the growth substrate GS, and then the thinned growth substrate GS and the etching stop layer ESL are removed by wet etching using a hydrochloric acid-based etchant. As a result, the first cladding layer 103 (n-InP layer) of the second laminate is exposed.

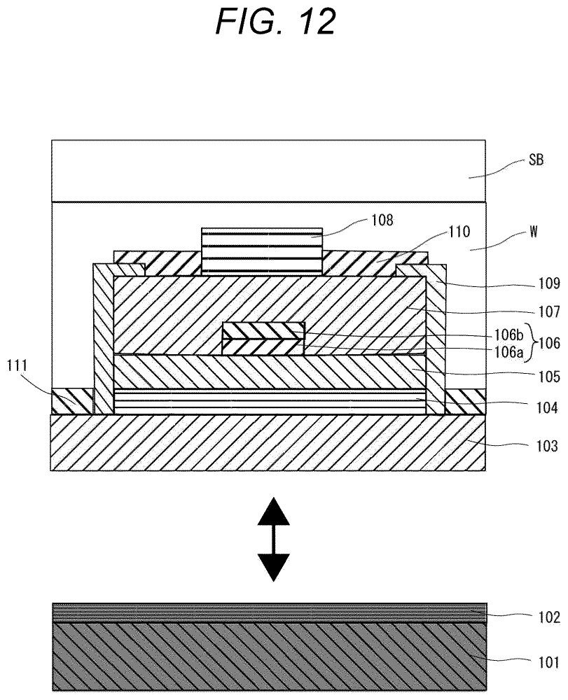

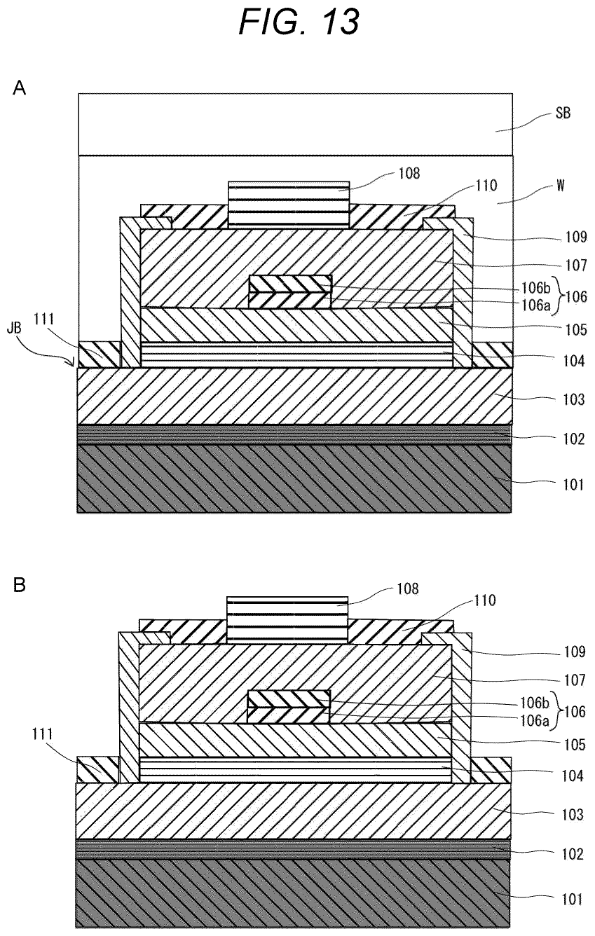

In the next step S12, the first and second laminates are bonded (See FIG. 12 and FIG. 13A). Specifically, the surface of the first laminate on the side corresponding to the first reflector 102 and the surface of the second laminate on the side corresponding to the first cladding layer 103 are bonded to each other by, for example, room-temperature bonding, plasma bonding, thermocompression bonding, or the like so as to face each other. In the joined body JB (see FIG. 13A) obtained by bonding, the first laminate inherently has no or substantially no warpage, so that the bonding interface is in a favorable state. Note that when there is dust or the like generated at the time of crystal growth on the surface of the first laminate corresponding to the first reflector 102, it is preferable to remove the dust or the like by wet etching, chemical mechanical polishing, or the like before bonding.

In the final step S13, the support substrate SB is removed (see FIG. 13B). Specifically, the wax W is melted by heating to remove the support substrate SB and the wax W. Then, cleaning and separation of the surface emitting lasers 10 are performed, and the anode electrode 110 and the cathode electrode 111 of each surface emitting laser 10 are connected to the corresponding terminals of the laser driver by, for example, wire bonding.

### <<Second Example of Method for Manufacturing Surface Emitting Laser>>

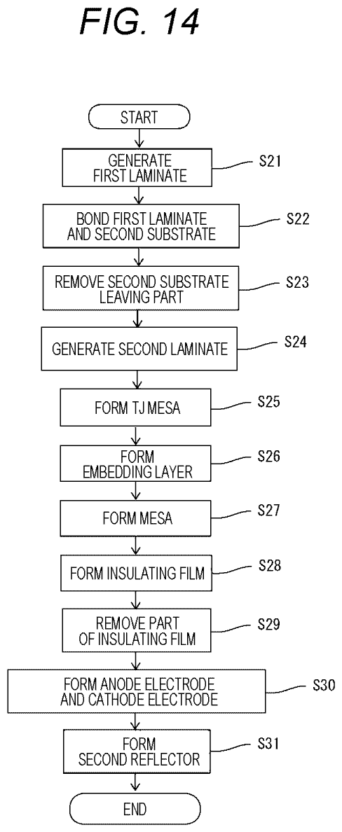

Hereinafter, a second example of a method for manufacturing the surface emitting laser 10 will be described with reference to the flowchart of FIG. 14, for example. Here, as an example, multiple surface emitting lasers 10 are simultaneously generated on one wafer which is the base material of the substrate 101 by a semiconductor manufacturing method using a semiconductor manufacturing apparatus. Next, the multiple surface emitting lasers 10 integrated in series are separated to obtain multiple chip-shaped surface emitting lasers 10 (surface emitting laser chips).

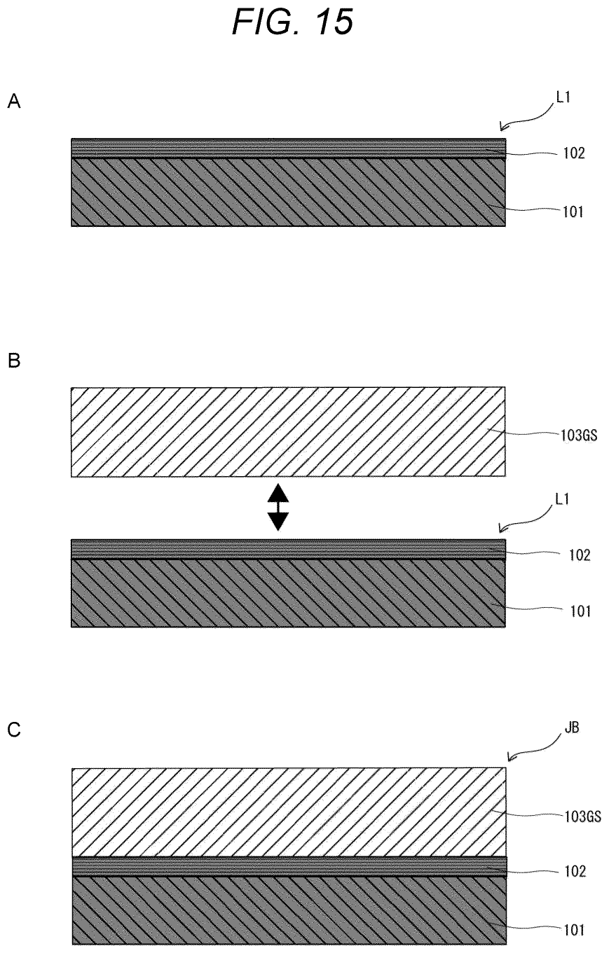

In the first step S21, a first laminate L1 is generated (see FIG. 15A). Specifically, the first reflector 102 is stacked on the substrate 101. More specifically, as an example, a GaAs-based compound semiconductor layer as a material of the first reflector 102 is epitaxially grown on the substrate 101 (Ge substrate) as the first substrate by a metal organic chemical vapor deposition (MOCVD) method.

In the next step S22, the first laminate L1 and a second substrate 103GS (for example, n-InP substrate) are bonded (see FIGS. 15B and 15C). Specifically, the surface of the first laminate L1 on the side corresponding to the first reflector 102 and one surface of the second substrate 103GS are bonded by, for example, room-temperature bonding, plasma bonding, thermocompression bonding, or the like so as to face each other. In the joined body JB obtained by bonding, the first laminate L1 inherently has no or substantially no warpage, so that the bonding interface is in a favorable state. Note that when there is dust or the like generated at the time of crystal growth on the surface of the first laminate corresponding to the first reflector 102, it is preferable to remove the dust or the like by wet etching, chemical mechanical polishing, or the like before bonding.

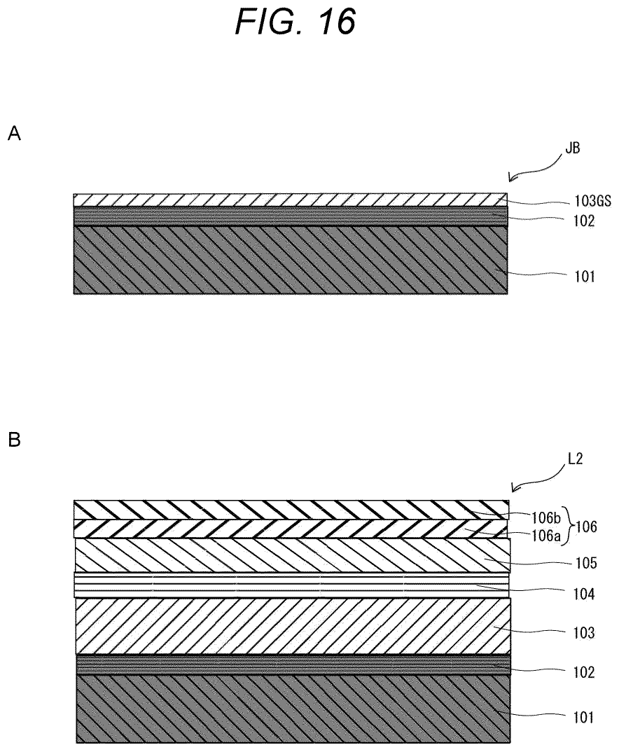

In the next step S23, the second substrate 103GS is removed while leaving a part (see FIG. 16A). Specifically, the surface of the joined body JB on the side corresponding to the second substrate 103GS is polished with a grinder or a CMP apparatus to thin the second substrate 103GS.

In the next step S24, the second laminate L2 is generated (see FIG. 16B). Specifically, as an example, the first cladding layer 103, the active layer 104, the second cladding layer 105, and the tunnel junction layer 106 are epitaxially grown in this order on the second substrate 103GS (growth substrate) of the joined body JB by a metal organic chemical vapor deposition method (MOCVD method).

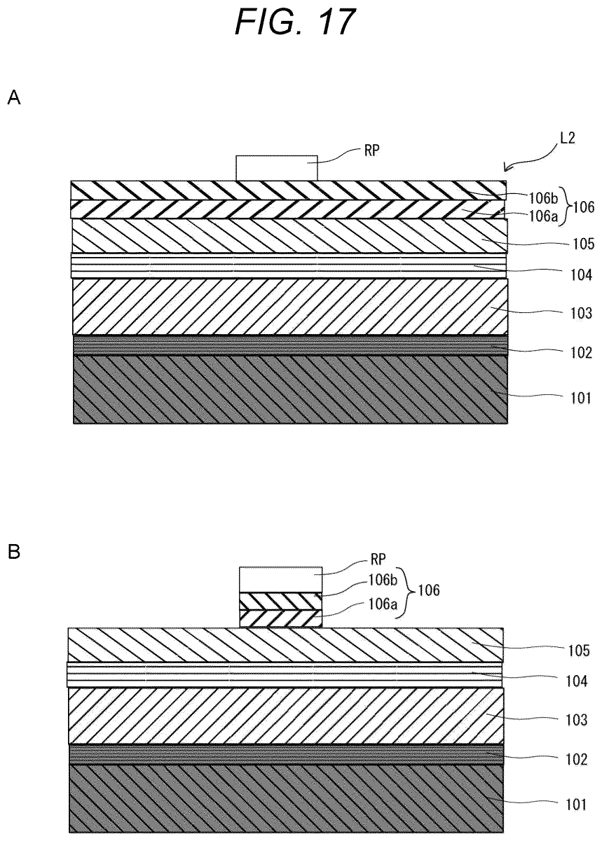

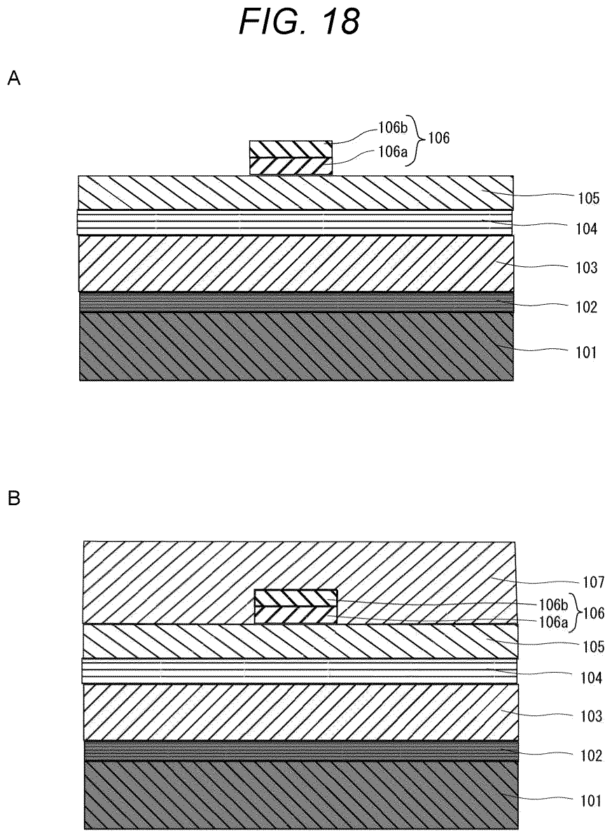

In the next step S25, a TJ mesa is formed. Specifically, first, a resist pattern RP that covers a portion where the TJ mesa is to be formed on the surface of the second laminate L2 on the side corresponding to the tunnel junction layer 106 is formed by photolithography (see FIG. 17A). Next, using the resist pattern RP as a mask, the tunnel junction layer 106 is etched by wet etching using a hydrochloric acid-based etchant to form a TJ mesa (see FIG. 17B). At this time, as an etchant for etching the n-type semiconductor region 106b (for example, the n-InP layer) of the tunnel junction layer 106, for example, a mixed solution of HCl, H₃PO₄, CH₃COOH, H₂O, or the like can be used. As an etchant for etching the p-type semiconductor region 106a (for example, a p-AlInAs layer), for example, a mixed solution of H₃PO₄, H₂O₂, H₂O, or the like can be used. Next, the resist pattern RP is removed by wet etching using an organic solvent or dry etching using a gas such as O₂, CF₄, or H₂ (see FIG. 18A).

In the next step S26, the third cladding layer 107 as an embedding layer is formed (see FIG. 18B). Specifically, as an example, the third cladding layer 107 (for example, an n-InP layer) as an embedding layer is regrown on the second laminate (on the second cladding layer 105) on which the TJ mesa is formed by the MOCVD method. As a result, the TJ mesa is embedded with the third cladding layer 107.

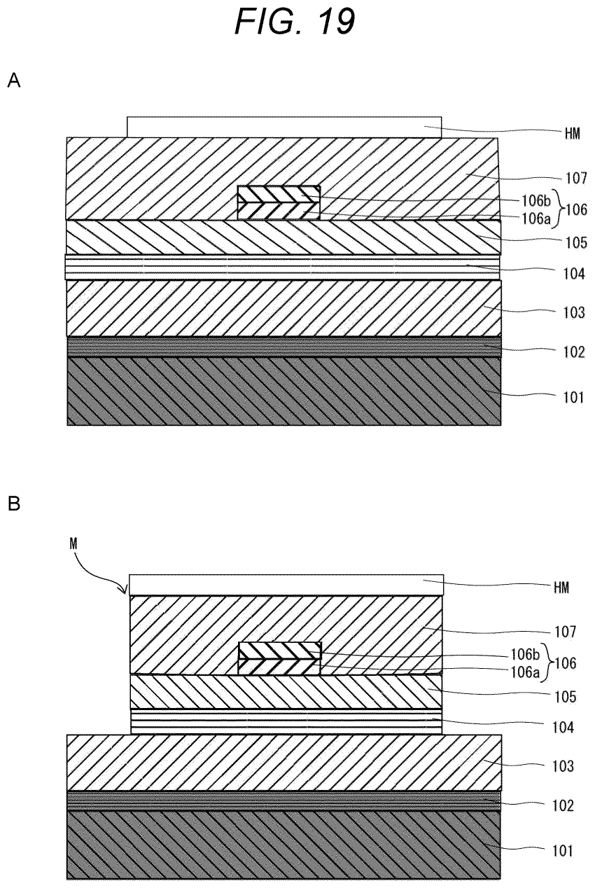

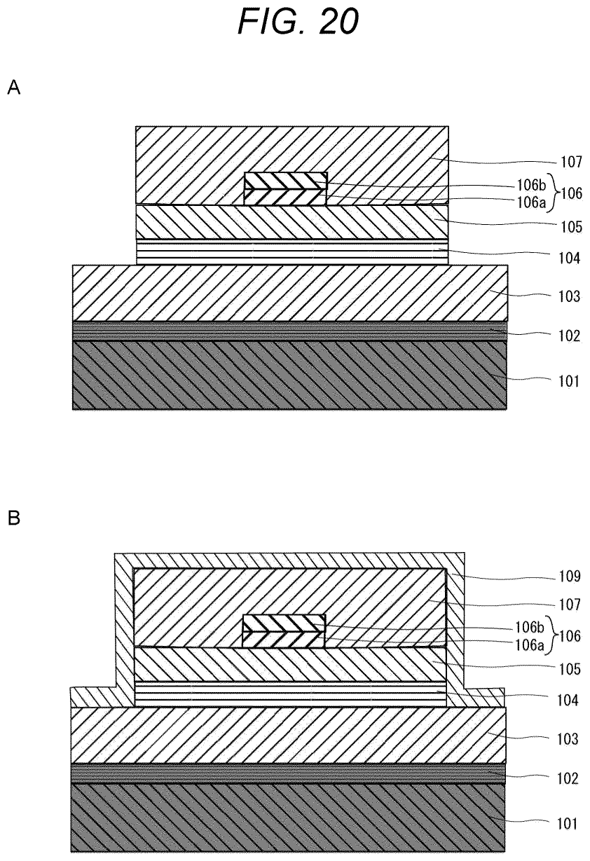

In the next step S27, a mesa M is formed. Specifically, first, a hard mask HM made of an oxide film (for example, a SiO₂ film) covering a portion of the third cladding layer 107 of the second laminate where the mesa M is to be formed is formed by photolithography (see FIG. 19A). At this time, the oxide film as the hard mask HM is formed by a CVD method, a sputtering method, a vapor deposition method, or the like, and the patterning of the oxide film is performed by wet etching using a hydrofluoric acid-based etchant using a resist pattern as a mask. Next, the second laminate is etched by dry etching using a Cl-based gas with the hard mask HM serving as a mask to form a mesa M (see FIG. 19B). At this time, for example, a mixed gas such as Cl₂, BCl₃, SiCl₄, Ar, or O₂ is used. The etching here is performed at least until the first cladding layer 103 is exposed. Then, the oxide film is removed by wet etching using a hydrofluoric acid-based etchant (see FIG. 20A).

In the next step S28, the insulating film 109 is formed (see FIG. 20B). Specifically, the insulating film 109 is formed on the entire surface of the second laminate.

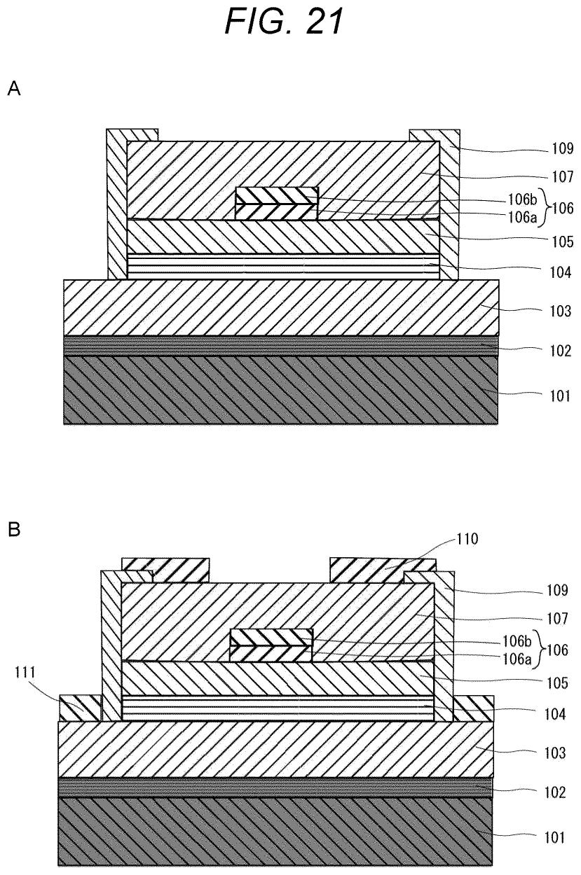

In the next step S29, a part of the insulating film 109 is removed (see FIG. 21A). Specifically, first, a resist pattern is formed by photolithography to cover a portion of the insulating film 109 other than the portion covering the top of the mesa M and the portion covering the region around the mesa M on the upper surface of the first cladding layer 103. Next, using the resist pattern as a mask, the second laminate is etched by dry etching using, for example, CF₄ gas, thereby exposing the top portion of the mesa M and the region of the upper surface of the first cladding layer 103 around the mesa M.

In the next step S30, the anode electrode 110 and the cathode electrode 111 are formed (see FIG. 21B). Specifically, for example, the loop-shaped (for example, ring-shaped) anode electrode 110 is formed on the periphery of the top portion of the mesa M by a lift-off method, and the cathode electrode 111 is formed on the region of the upper surface of the first cladding layer 103 around the mesa M. At this time, the electrode materials of the anode electrode 110 and the cathode electrode 111 are formed by a sputtering method or a vapor deposition method.

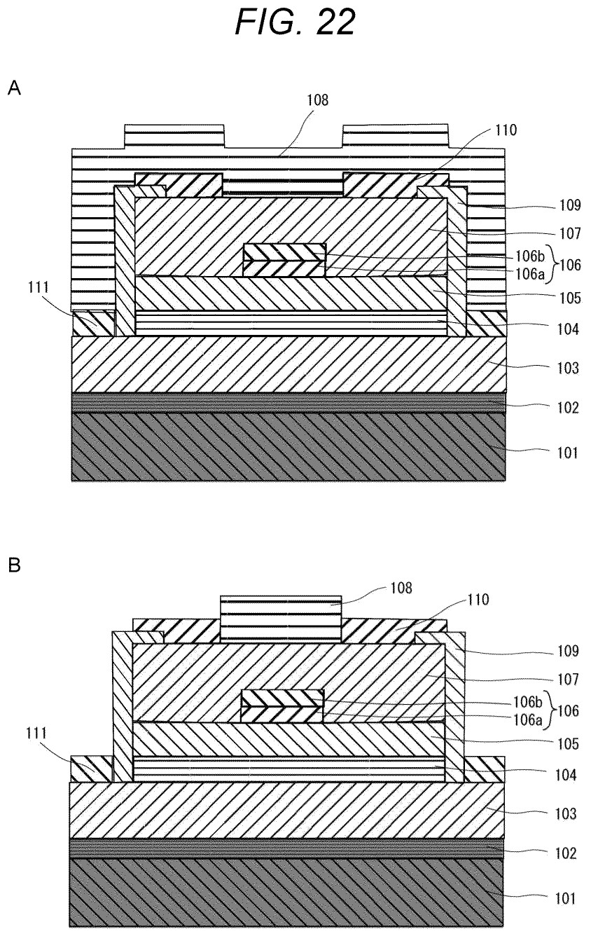

In the next step S31, the second reflector 108 is formed. Specifically, first, a dielectric multilayer film to be the material of the second reflector 108 is formed on the entire surface of the second laminate (see FIG. 22A). Next, a resist pattern is formed on the dielectric multilayer film covering the central portion of the top portion of the mesa M by photolithography. Next, the dielectric multilayer film is etched by dry etching or wet etching using the resist pattern as a mask (see FIG. 22B). As a result, the second reflector 108 is formed on the central portion of the top portion of the mesa M. Note that the second reflector 108 can also be formed by lift-off, for example.

### <<Effects of Surface Emitting Laser and Method for Manufacturing the Same>>

The surface emitting laser 10 according to the first embodiment of the present technology includes the resonator including the first structure ST1 including the substrate 101 and the first reflector 102 stacked on each other, the second structure ST2 that includes the second reflector 108 and is disposed on the side of the first Structure ST1 corresponding to the first reflector 102, and the intermediate structure IST that includes the active layer 104 and is disposed between the first and second structures ST1 and ST2. The substrate 101 includes a material having a lattice constant greater than a lattice constant of GaAs and less than a lattice constant of AlAs, and the first reflector 102 and the intermediate structure IST include different material systems.

In this case, for example, even when a GaAs-based material is used as the material system of the first reflector 102, it is possible to significantly reduce the warpage of the substrate 101 and the first reflector 102 as compared with a case where the GaAs-based semiconductor DBR is provided on the GaAs substrate. Furthermore, for example, an InP-based material different from a GaAs-based material can be used as the material system of the intermediate structure IST. As a supplementary explanation, the stress of the GaAs-based semiconductor multilayer film reflector epitaxially grown on the GaAs substrate is larger by one digit than the stress of the GaAs-based DBR epitaxially grown on the Ge substrate, for example, and a warpage correction film is required on the back surface of the GaAs substrate.

As a result, according to the surface emitting laser 10 of the first embodiment, it is possible to provide a surface emitting laser capable of obtaining desired characteristics (for example, an oscillation wavelength of an eye-safe band, characteristic having both high reflectivity and high heat dissipation, and the like) while suppressing occurrence of structural defects in the resonator R. More specifically, according to the surface emitting laser 10, it is possible to realize a high-efficiency and high-output surface emitting laser capable of performing high-temperature operation, improving yield and reliability, and performing laser oscillation in an eye-safe band.

The first reflector 102 preferably includes a material system lattice-matching with GaAs, and the intermediate structure IST preferably includes a material system lattice-matching with InP. As a result, it is possible to more reliably realize high-temperature operation, improvement in yield, improvement in reliability, laser oscillation in the eye-safe band, high efficiency, and high output.

The substrate 101 preferably includes Ge. As a result, the yield can be reliably improved, and the manufacturing cost can be reduced.

The first structure ST1 and the intermediate structure IST may be bonded. As a result, a resonator including different material systems can be easily realized.

A bonding layer may be formed between the first structure ST1 and the intermediate structure IST.

The intermediate structure IST includes the tunnel junction layer 106 stacked on the active layer 104, the intermediate structure IST includes the confinement portion that confines at least a current, and the confinement portion may include a high resistance region or an insulating region that is present in a peripheral portion of at least a part of the intermediate structure IST in the thickness direction. As a result, a current can be efficiently injected into the active layer 104. Furthermore, it is also possible to impart a light confinement function to the confinement portion.

The confinement portion may include a high resistance region or an insulating region that is present around the tunnel junction layer 106.

When the tunnel junction layer 106 has a mesa shape, the confinement portion can include a high resistance region present around the tunnel junction layer.

The tunnel junction layer 106 can be disposed on the opposite side of the active layer 104 from the substrate 101 side.

The second reflector 108 and the intermediate structure IST may include different material systems. As a result, the second reflector 108 can have characteristics (for example, reflectivity, heat dissipation, and the like) that are not limited by the material system of the intermediate structure IST.

The second reflector 108 may include a dielectric multilayer film reflector. In this case, it contributes to thinning of the surface emitting laser 10 while obtaining high reflectivity.

The first example of the method for manufacturing the surface emitting laser 10 includes a step of generating a first laminate L1 by stacking a first reflector 102 including the first material system on a substrate 101 (first substrate) including a material having a lattice constant greater than a lattice constant of GaAs and less than a lattice constant of AlAs, a step of generating a second laminate L2 by forming an intermediate structure IST (stacked structure) that includes a second material system and include an active layer 104 and a second reflector 108 in this order on a growth substrate GS (second substrate), a step of removing at least the growth substrate GS from the second laminate L2, and a step of bonding a surface of the first laminate L1 on the side corresponding to the first reflector 102 and a surface of the second laminate L2 on the side corresponding to the stacked structure so as to face each other.

As a result, the surface emitting laser 10 can be manufactured relatively easily.

The second example of the method for manufacturing the surface emitting laser 10 includes a step of generating a first laminate L1 by stacking a first reflector 102 including first material system on a substrate 101 (first substrate) including a material having a lattice constant greater than a lattice constant of GaAs and less than a lattice constant of AlAs, a step of generating the joined body JB by bonding the surface of the first laminate L1 on the side corresponding to the first reflector 102 and one surface of the second substrate 103GS so as to face each other, a step of removing a part of the second substrate 103GS from the joined body JB, and a step of generating a second laminate L2 by forming a stacked structure including the second material system and the second reflector 102 in this order on another portion of the second substrate 103GS of the joined body JB.

As a result, the surface emitting laser 10 can be relatively easily manufactured with fewer man-hours.

### 2. Surface Emitting Laser According to Second Embodiment of Present Technology

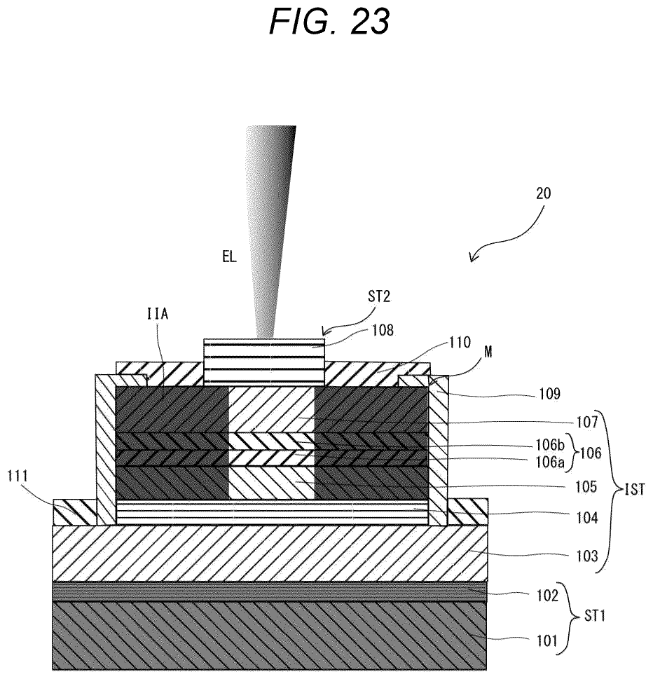

FIG. 23 is a cross-sectional view of a surface emitting laser 20 according to a second embodiment of the present technology. As illustrated in FIG. 23, the surface emitting laser 20 has a configuration similar to that of the surface emitting laser 10 according to the first embodiment except that an ion implantation region IIA is provided instead of the BTJ as a confinement portion.

In the surface emitting laser 20, the confinement portion is an ion implantation region IIA as a high resistance region present at least around the tunnel junction layer 106. The ion implantation region IIA is a loop-shaped (for example, annular) region surrounding at least the central portion of the tunnel junction layer 106. Here, in the tunnel junction layer 106, a low resistance central portion functions as a current passage region, and a high resistance peripheral portion where the ion implantation region IIA is formed functions as a current confinement region. The inner diameter (current confinement diameter) of the ion implantation region IIA is, for example, several um to several tens um. As the ion species of the ion implantation region IIA, for example, ions such as H, He, O, and B are used.

Here, the ion implantation region IIA is formed in the peripheral portion of the third cladding layer 107, the tunnel junction layer 106, and the second cladding layer 105, but is not limited thereto, and may be formed at least in the peripheral portion of the tunnel junction layer 106.

The surface emitting laser 20 can be manufactured by a manufacturing method substantially similar to the manufacturing method of the surface emitting laser 10 according to the first embodiment. However, in the method for manufacturing the surface emitting laser 20, although it is necessary to perform ion implantation, it is not necessary to perform TJ mesa formation and embedded regrowth, so that the manufacturing process is simplified and the manufacturing cost can be reduced.

The ion implantation may be performed either before or after the formation of the mesa M.

According to the surface emitting laser 20, it is possible to provide a surface emitting laser capable of obtaining substantially similar effects as the surface emitting laser 10 according to the first embodiment and reducing the manufacturing cost.

### 3. Surface Emitting Laser According to Third Embodiment of Present Technology

### (Example 1)

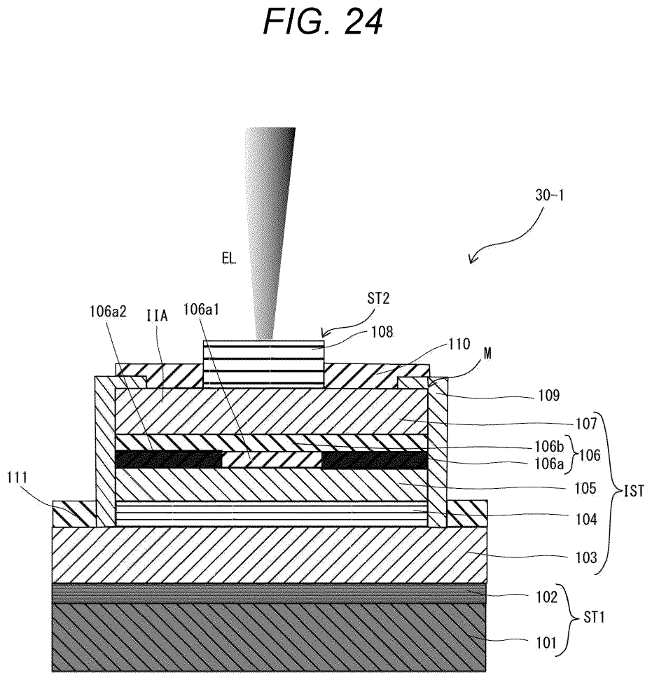

FIG. 24 is a cross-sectional view of a surface emitting laser 30-1 according to Example 1 of a third embodiment of the present technology. As illustrated in FIG. 24, the surface emitting laser 30-1 has a similar configuration as the surface emitting laser 20 according to the second embodiment except that an oxidized region is provided instead of the ion implantation region IIA as a confinement portion.

In the surface emitting laser 30-1, the confinement portion is an oxidized region as an insulating region present around the tunnel junction layer 106. More specifically, in the surface emitting laser 30-2, an oxidized region 106a2 as an insulating region is present around the p-InAlAs layer as a p-type semiconductor region 106a of the tunnel junction layer 106. The oxidized region 106a2 is provided in a loop shape (annular shape) so as to surround a non-oxidized region 106a1 of the p-InAlAs layer. The oxidized region 106a2 includes an oxide (for example, Al₂O₃) generated by selectively oxidizing the p-InAlAs layer from the side surface. The oxidized region 106a2 as a confinement portion has a current confinement function due to insulating properties and a light confinement function due to a difference in refractive index from the non-oxidized region 106a1. The inner diameter (confinement diameter) of the oxidized region 106a2 is, for example, several um to several tens μm.

### (Example 2)

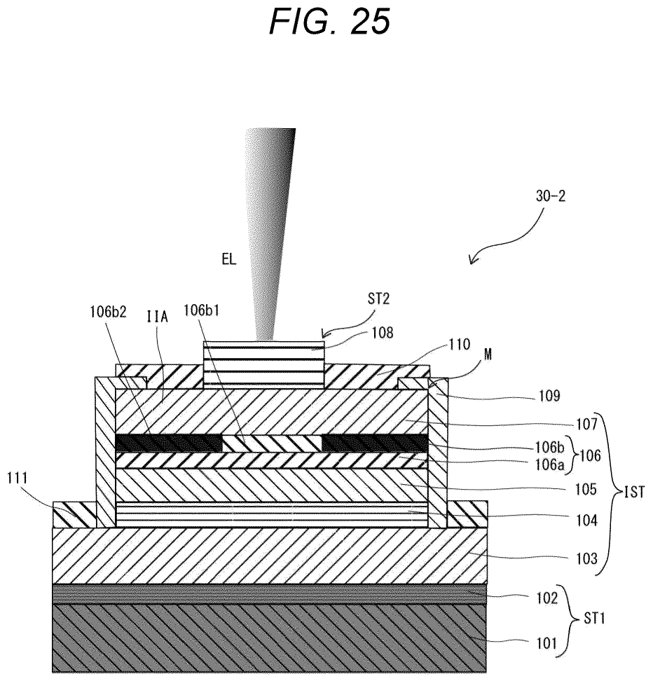

FIG. 25 is a cross-sectional view of a surface emitting laser 30-2 according to Example 2 of the third embodiment of the present technology. As illustrated in FIG. 25, the surface emitting laser 30-2 has a configuration substantially similar to that of the surface emitting laser 30-1 according to Example 1 except that an oxidized region as a confinement portion is provided in the n-type semiconductor region 106b of the tunnel junction layer 106.

In the surface emitting laser 30-2, the n-type semiconductor region 106b of the tunnel junction layer 106 includes an n-InAlAs layer. In the surface emitting laser 30-2, the confinement portion is an oxidized region 106b2 as an insulating region present around the n-type semiconductor region 106b (n-InAlAs layer) of the tunnel junction layer 106. The oxidized region 106b2 is provided in a loop shape (annular shape) so as to surround the non-oxidized region 106b1 of the n-InAlAs layer. The oxidized region 106b2 includes an oxide (for example, Al₂O₃) generated by selectively oxidizing the n-InAlAs layer from the side surface. The oxidized region 106b2 as a confinement portion has a current confinement function due to insulating properties and a light confinement function due to a difference in refractive index from the non-oxidized region 106b1. The inner diameter (confinement diameter) of the oxidized region 106b2 is, for example, several um to several tens um.

### (Example 3)

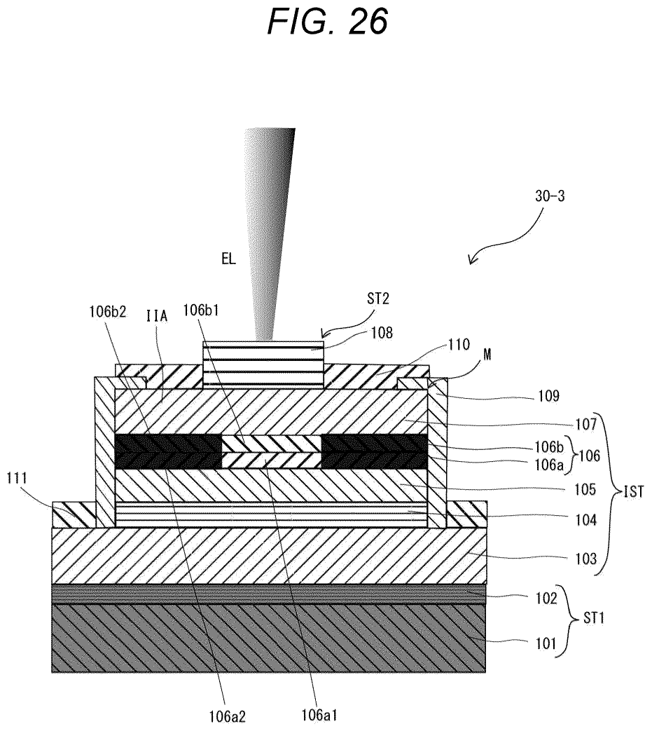

FIG. 26 is a cross-sectional view of a surface emitting laser 30-3 according to Example 3 of the third embodiment of the present technology. As illustrated in FIG. 26, the surface emitting laser 30-3 has a configuration substantially similar to that of the surface emitting laser 30-1 according to Example 1 except that an oxidized region as a confinement portion is provided in both the p-type semiconductor region 106a and the n-type semiconductor region 106b of the tunnel junction layer 106.

In the surface emitting laser 30-3, the p-type semiconductor region 106a of the tunnel junction layer 106 includes a p-InAlAs layer, and the n-type semiconductor region 106b includes an n-InAlAs layer. In the surface emitting laser 30-3, the confinement portion includes an oxidized region 106a2 as an insulating region present around the p-type semiconductor region 106a (p-InAlAs layer) of the tunnel junction layer 106 and an oxidized region 106b2 as an insulating region present around the n-type semiconductor region 106b (n-InAlAs layer). The oxidized region 106a2 is provided in a loop shape (annular shape) so as to surround a non-oxidized region 106a1 of the p-InAlAs layer. The oxidized region 106b2 is provided in a loop shape (annular shape) so as to surround the non-oxidized region 106b1 of the n-InAlAs layer. The oxidized region 106a2 includes an oxide (for example, Al₂O₃) generated by selectively oxidizing the p-InAlAs layer from the side surface. The oxidized region 106b2 includes an oxide (for example, Al₂O₃) generated by selectively oxidizing the n-InAlAs layer from the side surface. The oxidized region 106a2 of the confinement portion has a current confinement function due to insulating properties and a light confinement function due to a difference in refractive index from the non-oxidized region 106a1. The inner diameter (confinement diameter) of the oxidized region 106a2 is, for example, several um to several tens um. The oxidized region 106b2 of the confinement portion has a current confinement function due to insulating properties and a light confinement function due to a difference in refractive index from the non-oxidized region 106b1. The inner diameter (confinement diameter) of the oxidized region 106b2 is substantially the same as the inner diameter of the oxidized region 106a2 (for example, several um to several tens um).

The surface emitting lasers 30-1 to 30-3 according to Examples 1 to 3 of the third embodiment can be manufactured by a manufacturing method substantially similar to the manufacturing method of the surface emitting laser 10 according to the first embodiment. However, in the method for manufacturing the surface emitting lasers 30-1 to 30-3, although it is necessary to perform the oxidation step, it is not necessary to perform TJ mesa formation and embedded regrowth, so that the manufacturing process is simplified and the manufacturing cost can be reduced. The oxidation step can be performed after the formation of the mesa M.

According to the surface emitting lasers 30-1 to 30-3, it is possible to provide a surface emitting laser capable of obtaining substantially similar effects as the surface emitting laser 10 according to the first embodiment and reducing the manufacturing cost.

### 4. Surface Emitting Laser According to Fourth Embodiment of Present Technology

### (Example 1)

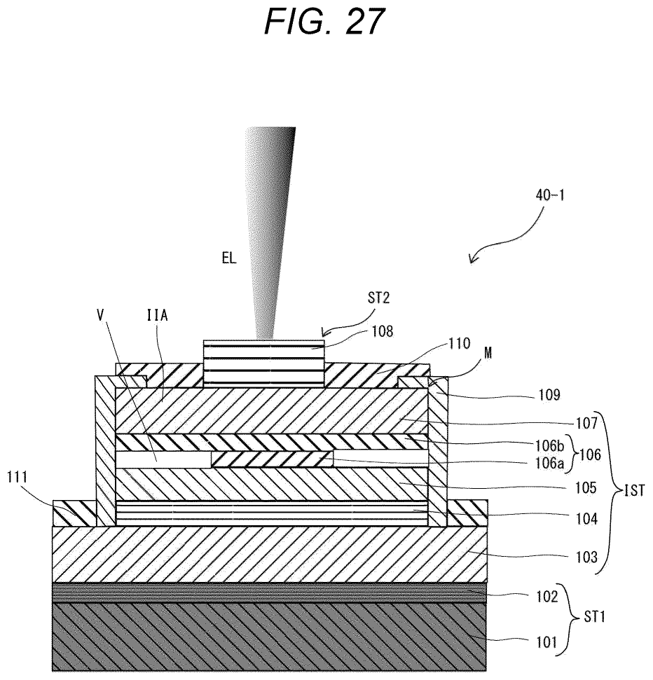

FIG. 27 is a cross-sectional view of a surface emitting laser 40-1 according to Example 1 of a fourth embodiment of the present technology. As illustrated in FIG. 27, the surface emitting laser 40-1 has a similar configuration as the surface emitting laser 30-1 according to Example 1 of the third embodiment except that a void V (air gap) is provided instead of the oxidized region as a confinement portion.

In the surface emitting laser 40-1, a loop-shaped void V surrounding the p-type semiconductor region 106a of the tunnel junction layer 106 is provided. The void V as a confinement portion has a current confinement function due to insulating properties and a light confinement function due to a difference in refractive index from the p-type semiconductor region 106a. The inner diameter (confinement diameter) of the void V is, for example, several um to several tens um.

### (Example 2)

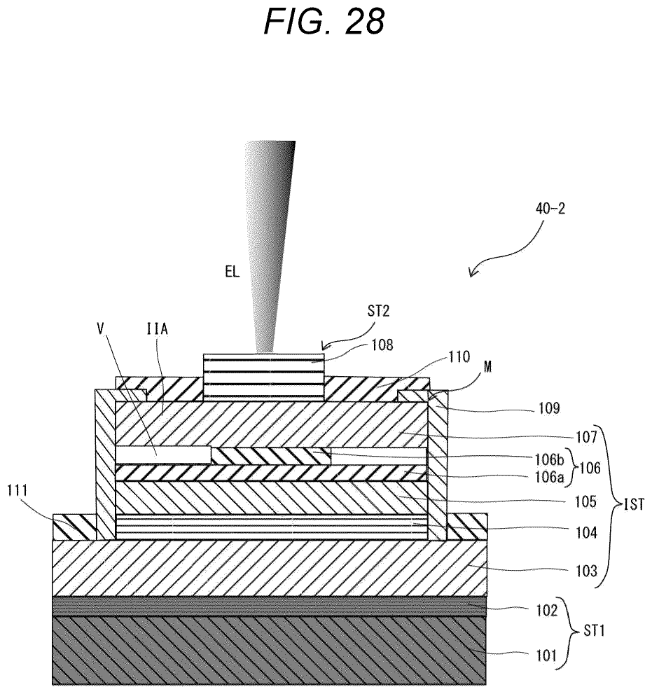

FIG. 28 is a cross-sectional view of a surface emitting laser 40-2 according to Example 2 of the fourth embodiment of the present technology. As illustrated in FIG. 28, the surface emitting laser 40-2 has a similar configuration as the surface emitting laser 40-1 according to Example 1 except that a void V (air gap) is provided around the n-type semiconductor region 106b of the tunnel junction layer 106 as a confinement portion.

In the surface emitting laser 40-2, a loop-shaped void V surrounding the n-type semiconductor region 106b of the tunnel junction layer 106 is provided. The void V as a confinement portion has a current confinement function due to insulating properties and a light confinement function due to a difference in refractive index from the n-type semiconductor region 106b. The inner diameter (confinement diameter) of the void V is, for example, several um to several tens um.

### (Example 3)

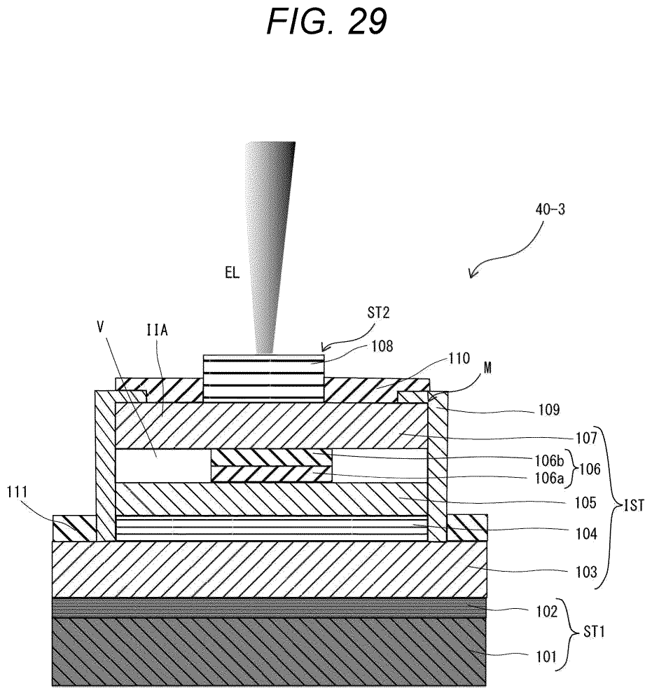

FIG. 29 is a cross-sectional view of a surface emitting laser 40-3 according to Example 3 of the fourth embodiment of the present technology. As illustrated in FIG. 29, the surface emitting laser 40-3 has a similar configuration as the surface emitting laser 40-1 according to Example 1 except that a void V (air gap) is provided around both the p-type semiconductor region 106a and the n-type semiconductor region 106b of the tunnel junction layer 106 as a confinement portion.

In the surface emitting laser 40-3, a loop-shaped void V surrounding the p-type semiconductor region 106a and the n-type semiconductor region 106b of the tunnel junction layer 106 are provided. The void V as a confinement portion has a current confinement function due to insulating properties, and has a light confinement function due to a difference in refractive index between the p-type semiconductor region 106a and the n-type semiconductor region 106b. The inner diameter (confinement diameter) of the void V is, for example, several um to several tens um.

The surface emitting lasers 40-1 to 40-3 according to Examples 1 to 3 of the fourth embodiment described above can be manufactured by a manufacturing method substantially similar to the manufacturing method of the surface emitting laser 10 according to the first embodiment. However, in the method for manufacturing the surface emitting lasers 40-1 to 40-3, after at least one of the p-type semiconductor region 106a and the n-type semiconductor region 106b of the tunnel junction layer 106 is formed in a mesa shape, it is necessary to grow the third cladding layer 107 so as to form the void V. At this time, the void V may be formed in a loop shape so as to surround at least a part of the tunnel junction layer 106 in the thickness direction.

According to the surface emitting lasers 40-1 to 40-3, it is possible to provide a surface emitting laser capable of obtaining substantially similar effects as the surface emitting laser 10 according to the first embodiment.

### 5. Surface Emitting Laser According to Fifth Embodiment of Present Technology

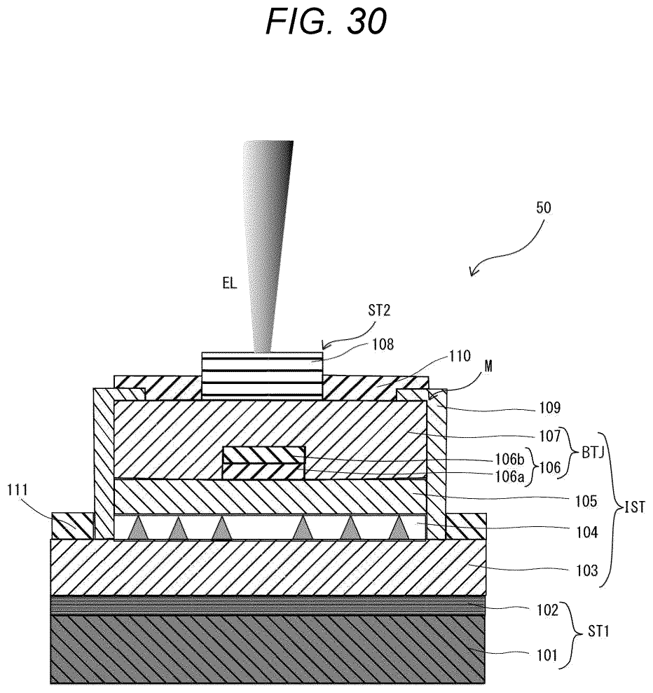

FIG. 30 is a cross-sectional view of a surface emitting laser 50 according to a fifth embodiment of the present technology. As shown in FIG. 30, the surface emitting laser 50 has a similar configuration as the surface emitting laser 10 according to the first embodiment except that the active layer 104 is a quantum dot active layer having quantum dots (for example, InAs). According to the surface emitting laser 50, it is possible to provide a surface emitting laser capable of obtaining effects similar to those of the surface emitting laser 10 according to the first embodiment and realizing a low threshold value.

### 6. Surface Emitting Laser According to Sixth Embodiment of Present Technology

### (Example 1)

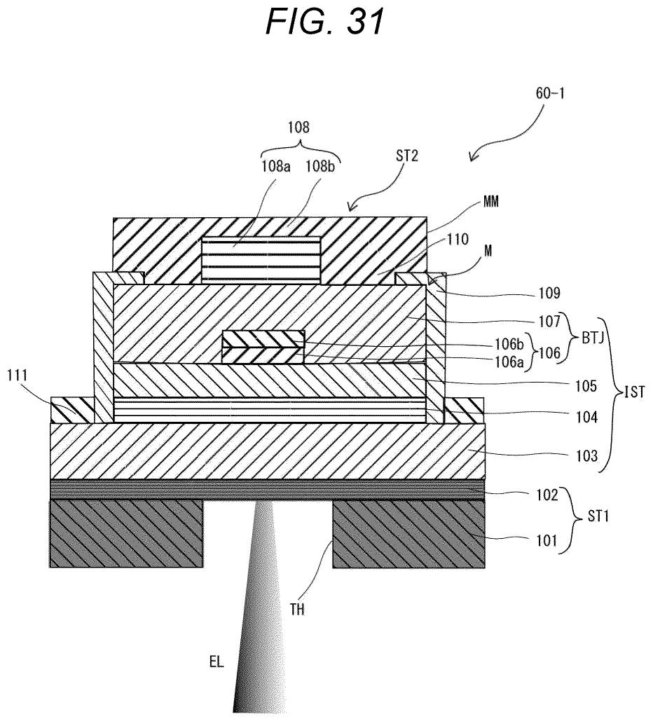

FIG. 31 is a cross-sectional view of a surface emitting laser 60-1 according to Example 1 of a sixth embodiment of the present technology. As illustrated in FIG. 31, the surface emitting laser 60-1 has a configuration substantially similar to that of the surface emitting laser 10 according to the first embodiment except that a through-hole TH is provided at a position corresponding to a region (tunnel junction layer 106) where the substrate 101 is surrounded by the third cladding layer 107 as a confinement portion, and light is emitted to the back surface side of the substrate 101. In the surface emitting laser 60-1, the heat dissipation is improved by providing the through-hole TH.

In the surface emitting laser 60-1, the second reflector 108 is a hybrid mirror including a dielectric multilayer film reflector 108a and a metal reflector 108b. The metal reflector 108b is a portion of a metal material MM provided so as to cover the dielectric multilayer film reflector 108a and stacked on the dielectric multilayer film reflector 108a. The other portion of the metal material MM functions as the anode electrode 110. The metal material MM may include the material of the anode electrode 110 (for example, a multilayer structure of Au/Ni/AuGe, Au/Pt/Ti, or the like), or may have a single-layer structure including, for example, Au, Ag, Cu, Al, or the like. The metal material MM also functions as a heat dissipation portion.

In the surface emitting laser 60-1, the reflectivity of the second reflector 108 is set to be slightly greater than the reflectivity of the first reflector 102.

The surface emitting laser 60-1 can be manufactured by a manufacturing method substantially similar to the manufacturing method of the surface emitting laser 10 according to the first embodiment except that the through-hole TH is formed in the substrate 101 and that the metal material MM is formed so as to cover the mesa M and the dielectric multilayer film reflector 108a.

According to the surface emitting laser 60-1, effects similar to those of the surface emitting laser 10 according to the first embodiment can be obtained, and it is possible to provide a backside emission type surface emitting laser suitable for high-temperature operation with higher efficiency and higher output.

Note that in the surface emitting laser 60-1, only the anode electrode 110 may be provided instead of the metal material MM (see, for example, FIG. 1).

### (Example 2)

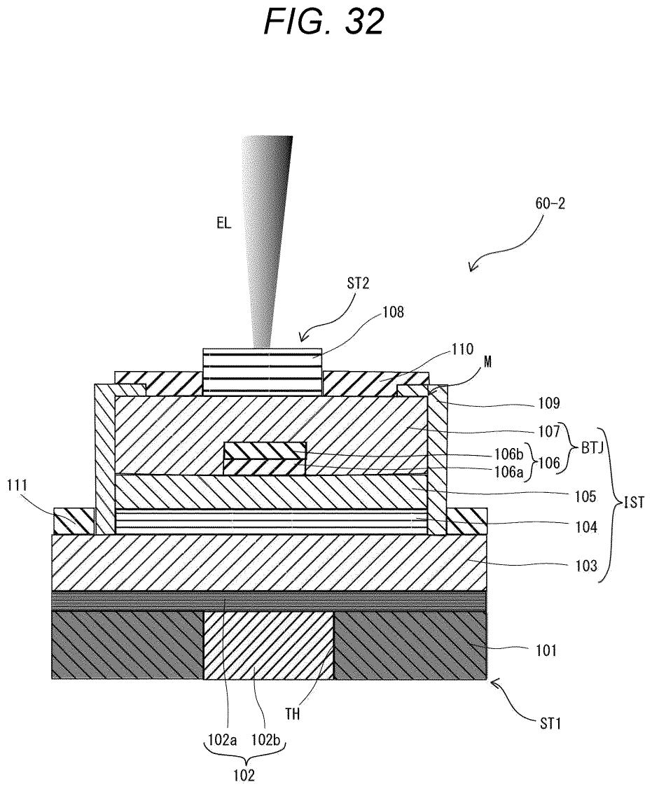

FIG. 32 is a cross-sectional view of a surface emitting laser 60-2 according to Example 2 of the sixth embodiment of the present technology. As illustrated in FIG. 32, the surface emitting laser 60-2 has a configuration substantially similar to that of the surface emitting laser 60-1 according to Example 1 except that a metal reflector 102b is provided in a through-hole TH provided in the substrate 101 and light is emitted to the front surface side of the substrate 101.

In the surface emitting laser 60-2, the first reflector 102 is a hybrid mirror including a semiconductor multilayer film reflector 102a (for example, a GaAs-based semiconductor multilayer film reflector) and a metal reflector 102b. The metal reflector 102b has a single-layer structure or a multilayer structure including, for example, Au, Ag, Cu, Al, or the like. The metal reflector 102b also functions as a heat dissipating portion.

The surface emitting laser 60-2 can be manufactured by a manufacturing method substantially similar to the manufacturing method of the surface emitting laser 10 according to the first embodiment except that the through-hole TH is formed in the substrate 101 and the metal reflector 102b is formed in the through-hole TH.

According to the surface emitting laser 60-2, effects similar to those of the surface emitting laser 10 according to the first embodiment can be obtained, and it is possible to provide a surface emitting type surface emitting laser suitable for high-temperature operation with higher efficiency and higher output.

### (Example 3)

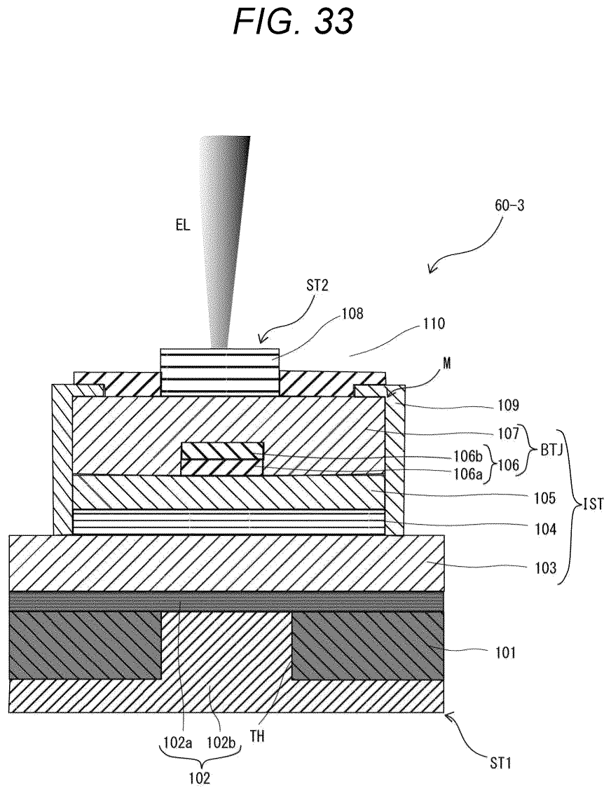

FIG. 33 is a cross-sectional view of a surface emitting laser 60-3 according to Example 3 of the sixth embodiment of the present technology. As illustrated in FIG. 33, the surface emitting laser 60-3 has a configuration substantially similar to that of the surface emitting laser 60-2 according to Example 2 except that a metal reflector 102b is provided in a through-hole TH provided in the substrate 101 and on the back surface of the substrate 101.

In the surface emitting laser 60-3, the metal reflector 102b constituting a hybrid mirror together with the semiconductor multilayer film reflector 102a (for example, a GaAs-based semiconductor multilayer film reflector) is provided on the back surface of the substrate 101 in a state where a part thereof is in the through-hole TH. That is, in the surface emitting laser 60-3, the metal reflector 102b, which also serves as a part of the first reflector 102 and the dissipation portion, is enlarged. The metal reflector 102b has a single-layer structure or a multilayer structure including, for example, Au, Ag, Cu, Al, or the like.

The surface emitting laser 60-3 can be manufactured by a manufacturing method substantially similar to the manufacturing method of the surface emitting laser 10 according to the first embodiment except that the through-hole TH is formed in the substrate 101 and the metal reflector 102b is formed in the through-hole TH and on the back surface of the substrate 101.

According to the surface emitting laser 60-3, effects similar to those of the surface emitting laser 10 according to the first embodiment can be obtained, and it is possible to provide a surface emitting type surface emitting laser suitable for high-temperature operation with higher efficiency and higher output.

### 7. Surface Emitting Laser According to Seventh Embodiment of Present Technology

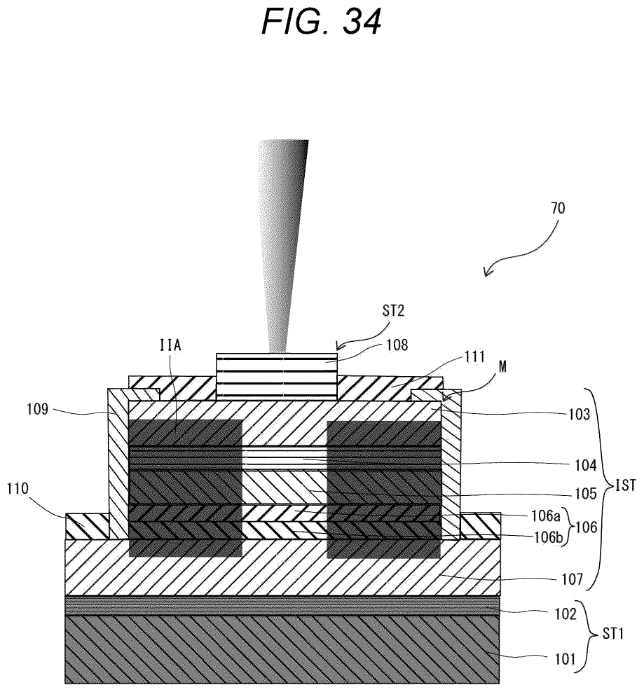

FIG. 34 is a cross-sectional view of a surface emitting laser 70 according to a seventh embodiment of the present technology. As illustrated in FIG. 34, the surface emitting laser 70 has a similar configuration as the surface emitting laser 20 according to the second embodiment except that the intermediate structure IST has a vertically inverted configuration and the positional relationship between the anode electrode 110 and the cathode electrode 111 is reversed.

In the surface emitting laser 70, the tunnel junction layer 106 is disposed on the side of the active layer 104 corresponding to the substrate 101. More specifically, in the surface emitting laser 70, the third cladding layer 107, the tunnel junction layer 106, the second cladding layer 105, the active layer 104, and the first cladding layer 103 are stacked in this order on the first structure ST1.

In the surface emitting laser 70, the p-type semiconductor region 106a is disposed on the side of the n-type semiconductor region 106b corresponding to the active layer 104 (the upper side) in the tunnel junction layer 106. In the surface emitting laser 70, the anode electrode 110 is provided on a region around the mesa M on the upper surface of the third cladding layer 107, and the cathode electrode 111 is provided in a loop shape (annular shape) so as to surround the second reflector 108 at the top of the mesa M.

In the surface emitting laser 70, the ion implantation region IIA is not provided at least on the surface layer on the opposite side of the first cladding layer 103 from the active layer 104 or the surface layer on the opposite side of the third cladding layer 107 from the active layer 104. In this case, since the ion implantation region IIA is not present on the current path from the anode electrode 110 to the cathode electrode 111, the current injection efficiency into the active layer 104 can be enhanced. As described above, in the surface emitting laser 70, the formation position of the ion implantation region IIA is optimized.

The surface emitting laser 70 can be manufactured by a manufacturing method substantially similar to the manufacturing method of the surface emitting laser 20 according to the second embodiment except that when the intermediate structure IST is formed by reverse epitaxial growth, a part of the first cladding layer 103 or the third cladding layer 107 is grown, then ion implantation is performed, and the remainder is regrown. Note that the formation position of the ion implantation region IIA can be optimized by introducing a technique of regrowing after ion implantation performed by the manufacturing method of the surface emitting laser 20 into the manufacturing of the surface emitting laser 70 according to the second embodiment.

According to the surface emitting laser 70, it is possible to obtain effects similar to those of the surface emitting laser 10 according to the first embodiment and to provide a more efficient surface emitting type surface emitting laser.

### 8. Surface Emitting Laser According to Eighth Embodiment of Present Technology

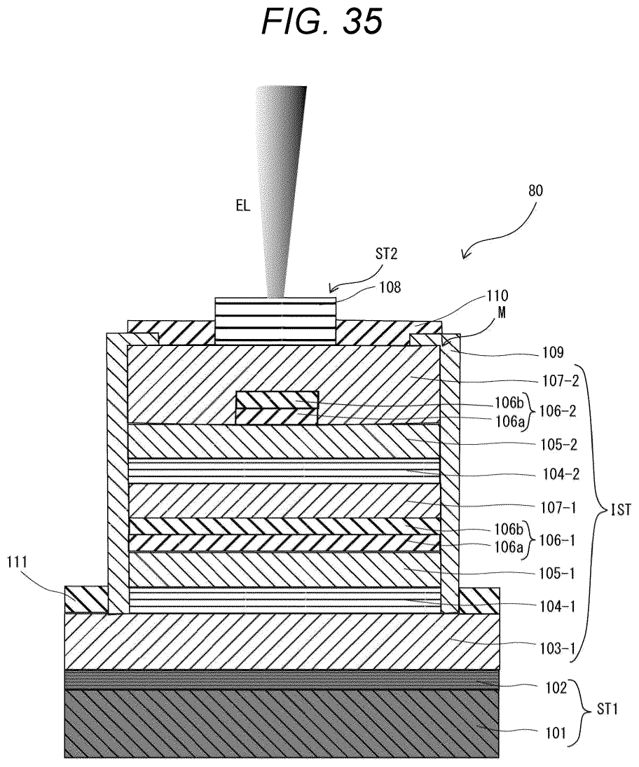

FIG. 35 is a cross-sectional view of a surface emitting laser 80 according to an eighth embodiment of the present technology. As illustrated in FIG. 35, the surface emitting laser 80 has a configuration substantially similar to that of the surface emitting laser 10 according to the first embodiment except that the intermediate structure IST includes multiple (for example, two) semiconductor structures stacked on each other, and each of these multiple semiconductor structures has an active layer and a tunnel junction layer.

In the surface emitting laser 80, the intermediate Structure IST includes a first semiconductor structure, which includes a first active layer 104-1 and a first tunnel junction layer 106-1 and is disposed on the first structure ST1, and a second semiconductor structure, which includes a second active layer 104-2 and a second tunnel junction layer 106-2 and is disposed on the first semiconductor structure.

In the first semiconductor structure, the first cladding layer 103-1 (for example, an n-InP layer), the first active layer 104-1, the second cladding layer 105-1 (for example, a p-InP layer), the first tunnel junction layer 106-1, and the third cladding layer 107-1 (for example, an n-InP layer) are stacked in this order from the side corresponding to the first structure ST1. In the second semiconductor structure, the third cladding layer 107-1 (for example, an n-InP layer), the second active layer 104-2, the second cladding layer 105-2 (for example, a p-InP layer), the second tunnel junction layer 106-2, and the third cladding layer 107-2 (for example, an n-InP layer) are stacked in this order from the first semiconductor structure side. The third cladding layer 107-1 is shared by the first and second semiconductor structures.

In the surface emitting laser 80, since the first tunnel junction layer 106-1 is disposed between the first and second active layers 104-1 and 104-2, currents of substantially the same magnitude can flow through the first and second active layers 104-1 and 104-2.

The first tunnel junction layer 106-1 has a broad flat shape. The second tunnel junction layer 106-2 has a mesa shape and constitutes a BTJ together with the third cladding layer 107-2 as an embedding layer.

The surface emitting laser 80 can be manufactured by a manufacturing method substantially similar to the manufacturing method of the surface emitting laser 10 according to the first embodiment except that the first and second semiconductor structures are stacked.

According to the surface emitting laser 80, it is possible to provide a surface emitting type surface emitting laser capable of obtaining effects similar to those of the surface emitting laser 10 according to the first embodiment and further increasing the output by the multiple active layers.

Note that it is also possible to realize a high-output surface emitting laser having multiple active layers in which three or more active layers are stacked by a technique similar to that of the surface emitting laser 80.

### 9. Surface Emitting Laser According to Ninth Embodiment of Present Technology

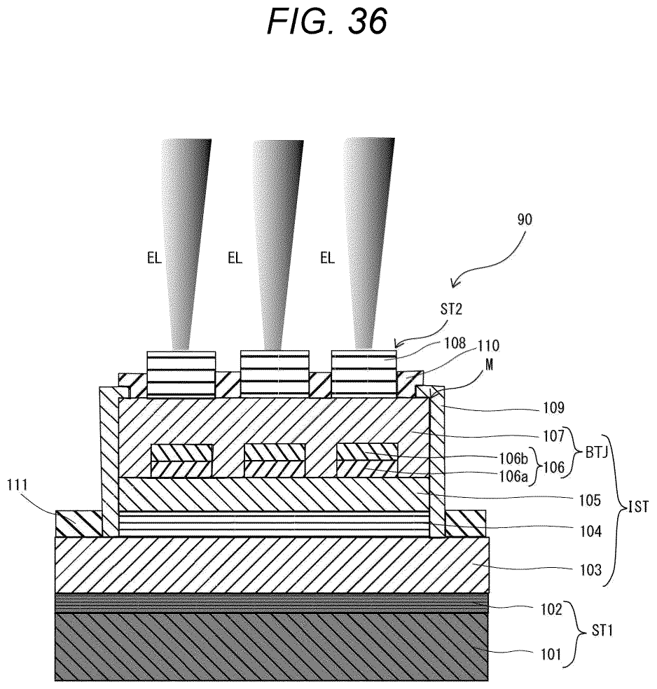

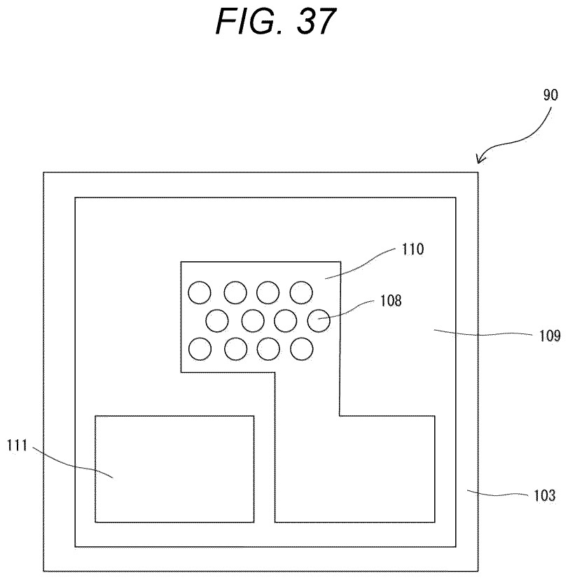

FIG. 36 is a cross-sectional view of a surface emitting laser 90 according to a ninth embodiment of the present technology. FIG. 37 is a plan view of the surface emitting laser 90 according to the eighth embodiment of the present technology. As illustrated in FIGS. 36 and 37, the surface emitting laser 90 has a configuration substantially similar to that of the surface emitting laser 10 according to the first embodiment except that multiple confinement portions are provided in the in-plane direction in the intermediate structure IST.

In the surface emitting laser 90, multiple sets of a mesa-shaped tunnel junction layer 106 (TJ mesa) and a confinement portion (a part of the third cladding layer 107) surrounding the TJ mesa are provided in the intermediate structure IST in the in-plane direction.

In the surface emitting laser 90, the first reflector 102 is provided so as to be shared by the multiple TJ mesas. The second reflector 108 has multiple reflection regions individually corresponding to the multiple TJ mesas. A region of the active layer 104 corresponding to each TJ mesa is a light emitting region. Here, both the anode electrode 110 and the cathode electrode 111 are provided in common in the multiple light emitting regions.

The surface emitting laser 90 can be manufactured by a manufacturing method substantially similar to the manufacturing method of the surface emitting laser 10 according to the first embodiment except that multiple TJ mesas are formed.

According to the surface emitting laser 90, it is possible to provide a surface emitting type surface emitting laser (substantially a surface emitting laser array) having multiple light emitting units and capable of obtaining effects similar to those of the surface emitting laser 10 according to the first embodiment.

For example, the anode electrode 110 may include electrode regions insulated from each other in the respective light emitting regions, so that the light emitting units can be independently driven.

### 10. Ranging Device According to Tenth Embodiment of Present Technology

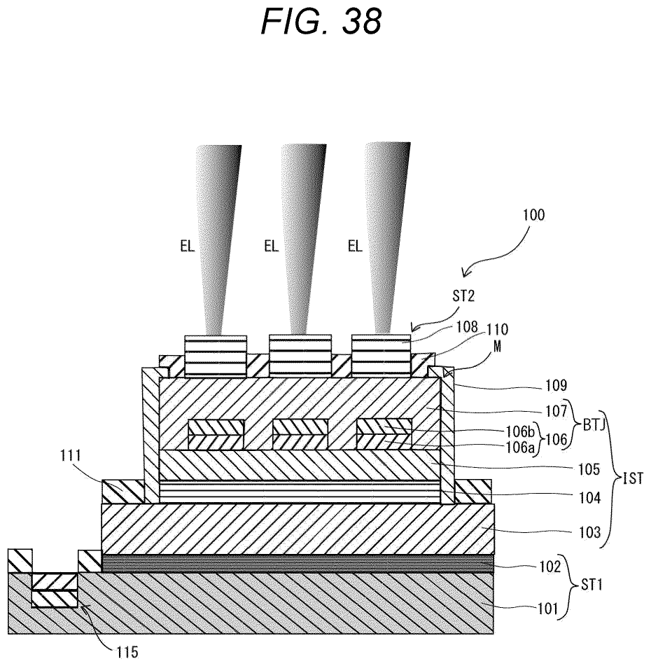

FIG. 38 is a cross-sectional view of a ranging device 100 according to a tenth embodiment of the present technology. As illustrated in FIG. 38, the ranging device 100 includes a surface emitting laser having substantially a similar configuration as the surface emitting laser 90 according to the ninth embodiment and a light receiving element 115 provided on a substrate 101 of the surface emitting laser.

As an example, the substrate 101 of the surface emitting laser of the ranging device 100 is a Ge substrate on which an IC including a laser driver and a light receiving circuit is formed. The light receiving circuit includes, for example, an A/D converter, a time of flight (TOF) calculation unit, and the like.

As an example, the light receiving element 115 is provided in a state where the light receiving surface is exposed in a hole portion formed in the surface of the substrate 101 in a region around the surface emitting laser. As an example, the light receiving element 115 is an avalanche photodiode (APD) made of SiGe having long wavelength sensitivity (having sensitivity in an eye-safe band).

The ranging device 100 can be manufactured by a manufacturing method substantially similar to the method for manufacturing the surface emitting laser 90 according to the ninth embodiment except that the IC and the light receiving element 115 are formed on the substrate 101.

According to the ranging device 100, it is possible to provide a high-performance eye-safe TOF module including the surface emitting laser array including the multiple light emitting units that achieve effects similar to those of the surface emitting laser 10 according to the first embodiment and the light receiving element 115 having long-wavelength sensitivity.

### 11. Surface Emitting Laser According to Eleventh Embodiment of Present Technology

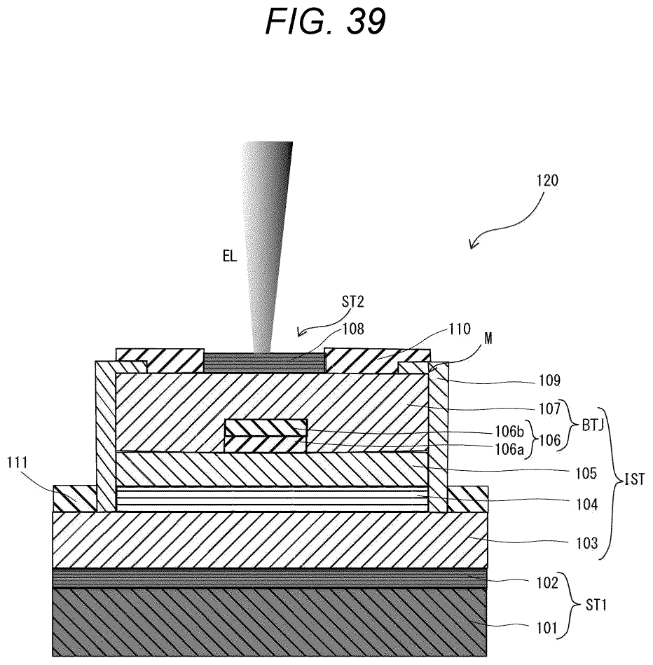

FIG. 39 is a cross-sectional view of a surface emitting laser 120 according to an eleventh embodiment of the present technology. As illustrated in FIG. 39, the surface emitting laser 120 has a configuration substantially similar to that of the surface emitting laser 10 according to the first embodiment except that the second reflector 108 is a semiconductor multilayer film reflector.

In the surface emitting laser 120, the second reflector 108 and the intermediate structure IST include different material systems. Specifically, in the surface emitting laser 120, the second reflector 108 includes a GaAs-based material, and the intermediate structure IST includes an InP-based material.

In the surface emitting laser 120, the first and second reflectors 102 and 108 include the same material system. Specifically, in the surface emitting laser 120, each of the first and second reflectors 102 and 108 includes a material system (GaAs system) lattice-matching with GaAs. Specifically, each of the first and second reflectors 102 and 108 is a GaAs-based semiconductor multilayer film reflector. The second reflector 108 is disposed on the inner diameter side of the anode electrode 110. The GaAs-based semiconductor multilayer film reflector as the second reflector 108 may be, for example, undoped i-type or doped with p-type doping. The second reflector 108 of the second structure ST2 and the third cladding layer 107 of the intermediate structure IST are bonded. A bonding layer may be formed between the second reflector 108 and the third cladding layer 107.

The surface emitting laser 120 can be manufactured by a manufacturing method substantially similar to the manufacturing method of the surface emitting laser 10 according to the first embodiment except that the second reflector 108 and the third cladding layer 107 are bonded.

In the surface emitting laser 120, since the GaAs-based semiconductor multilayer film reflector is used as the second reflector 108, heat dissipation can be improved as compared with a case where a dielectric multilayer film reflector is used.

According to the surface emitting laser 120, it is possible to provide a surface emitting type surface emitting laser that is capable of obtaining effects similar to those of the surface emitting laser 10 according to the first embodiment and is suitable for high-temperature operation.

### 12. Surface Emitting Laser According to Twelfth Embodiment of Present Technology

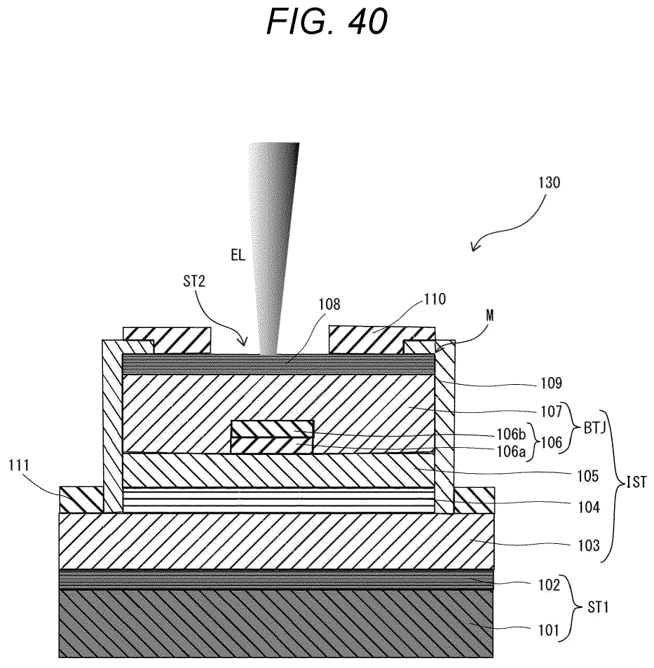

FIG. 40 is a cross-sectional view of a surface emitting laser 130 according to a twelfth embodiment of the present technology. As illustrated in FIG. 40, the surface emitting laser 130 has a configuration substantially similar to that of the surface emitting laser 120 according to the eleventh embodiment except that an anode electrode 110 is provided on a GaAs-based semiconductor multilayer film reflector as the second reflector 108.

In the surface emitting laser 130, a GaAs-based semiconductor multilayer film reflector as the second reflector 108 is doped with p-type doping, for example. As a result, a current can flow from the anode electrode 110 to the intermediate structure IST via the second reflector 108.

The surface emitting laser 130 can be manufactured by a manufacturing method substantially similar to the manufacturing method of the surface emitting laser 10 according to the first embodiment except that the second reflector 108 and the third cladding layer 107 are bonded and the anode electrode 110 is formed on the second reflector 108.

In the surface emitting laser 130, since the GaAs-based semiconductor multilayer film reflector is used as the second reflector 108, heat dissipation can be improved as compared with a case where the dielectric multilayer film reflector is used.

According to the surface emitting laser 130, it is possible to provide a surface emitting type surface emitting laser that is capable of obtaining effects similar to those of the surface emitting laser 10 according to the first embodiment and is suitable for high-temperature operation.

### 13. Surface Emitting Laser According to Thirteenth Embodiment of Present Technology

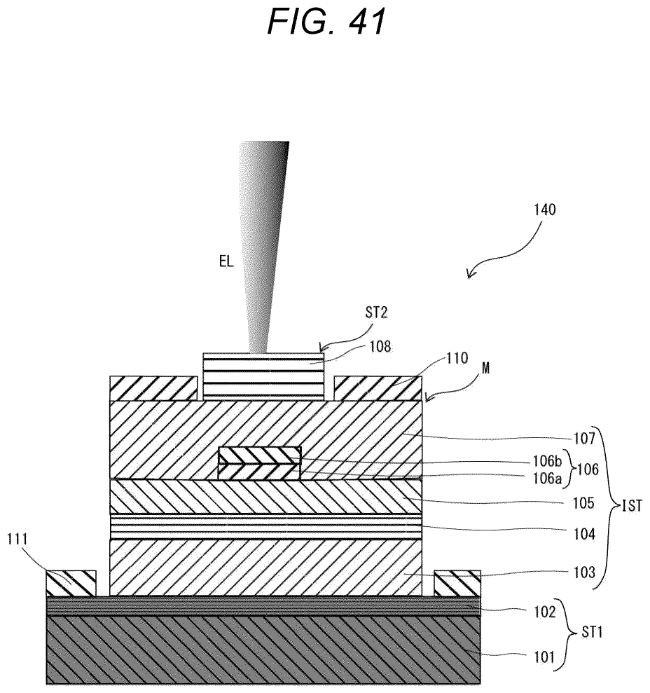

FIG. 41 is a cross-sectional view of a surface emitting laser 140 according to a thirteenth embodiment of the present technology. As illustrated in FIG. 41, the surface emitting laser 140 has a configuration substantially similar to that of the surface emitting laser 10 according to the first embodiment except that the bottom surface of the mesa M coincides with the upper surface of the first reflector 102.

In the surface emitting laser 140, the GaAs-based semiconductor multilayer film reflector as the first reflector 102 is doped with n-type doping, and the cathode electrode 111 is provided on the first reflector 102.

The surface emitting laser 140 can be manufactured by a manufacturing method substantially similar to the manufacturing method of the surface emitting laser 10 according to the first embodiment except that the first cladding layer 103 is also etched at the time of forming the mesa M and the cathode electrode 111 is provided on the first reflector 102.

According to the surface emitting laser 140, it is possible to provide a surface emitting laser capable of obtaining effects similar to those of the surface emitting laser 10 according to the first embodiment.

### 14. Surface Emitting Laser According to Fourteenth Embodiment of Present Technology

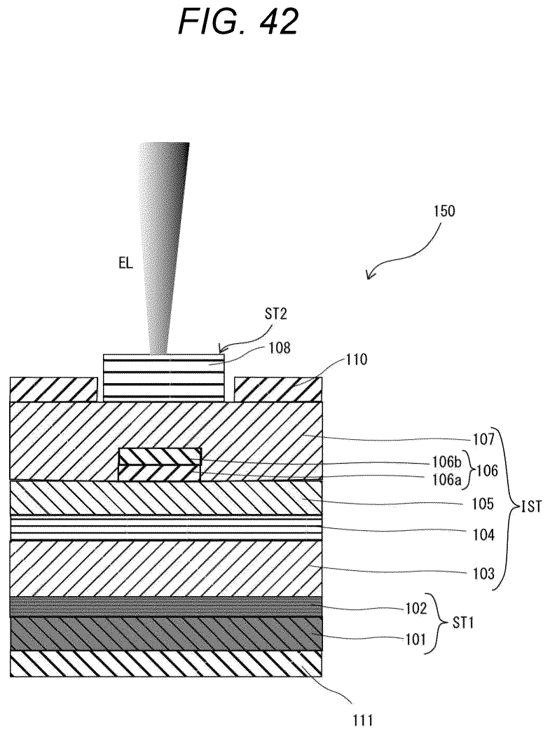

FIG. 42 is a cross-sectional view of a surface emitting laser 150 according to a fourteenth embodiment of the present technology. As illustrated in FIG. 42, the surface emitting laser 150 has a configuration substantially similar to that of the surface emitting laser 10 according to the first embodiment except that it has a mesa-free structure and a back electrode structure.

In the surface emitting laser 150, the substrate 101 and the first reflector 102 are doped with n-type doping, and the cathode electrode 111 is solidly provided on the back surface of the substrate 101.

The surface emitting laser 150 can be manufactured by a manufacturing method substantially similar to the manufacturing method of the surface emitting laser 10 according to the first embodiment except that the mesa forming step is unnecessary and the cathode electrode 111 is provided on the back surface of the substrate 101.

According to the surface emitting laser 150, it is possible to provide a surface emitting type surface emitting laser that has a back electrode type mesa-free structure and is capable of obtaining effects similar to those of the surface emitting laser 10 according to the first embodiment.

### 15. Surface Emitting Laser According to Fifteenth Embodiment of Present Technology

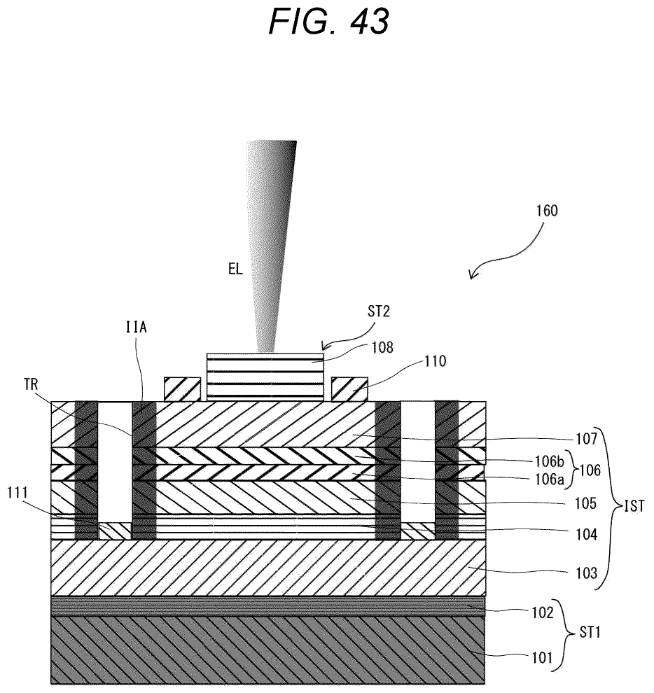

FIG. 43 is a cross-sectional view of a surface emitting laser 160 according to a fifteenth embodiment of the present technology. As illustrated in FIG. 43, the surface emitting laser 160 has a configuration substantially similar to that of the surface emitting laser 20 according to the second embodiment except that it has a mesa-free structure.

In the surface emitting laser 160, multiple trenches TR (grooves) are formed in the peripheral portion of the intermediate structure IST. Here, the bottom surface of each trench TR is the upper surface of the first cladding layer 103, and the cathode electrode 111 is provided on the bottom surface. Note that a via (hole) may be provided instead of the trench TR. Furthermore, the bottom surface of the trench TR where the cathode electrode 111 is provided may be located in the first cladding layer 103. In addition, when the first reflector 102 has conductivity, the bottom surface of the trench TR may be the upper surface of the first reflector 102 or may be located in the first reflector 102. In addition, for example, when the substrate 101 and the first reflector 102 have conductivity, the bottom surface of the trench TR may be the upper surface of the substrate 101 or may be positioned in the substrate 101.

An ion implantation region IIA surrounding the light emitting unit is provided in the intermediate structure IST. As an example, multiple (for example, two) ion implantation regions IIA are provided substantially concentrically in plan view. The ion implantation region IIA has both a function of substantially insulating the cathode electrode 111 from a portion of the intermediate structure IST other than the first cladding layer 103, and a current confinement function. The anode electrode 110 is provided on the upper surface of the third cladding layer 107 of a region inside the ion implantation region IIA.

The surface emitting laser 160 can be manufactured by a method substantially similar to the manufacturing method of the surface emitting laser 20 according to the second embodiment except that the trenches TR are formed and the cathode electrode 111 is provided on the bottom surfaces of the trenches TR.

According to the surface emitting laser 160, it is possible to provide a surface emitting type surface emitting laser having a mesa-free structure capable of obtaining effects similar to those of the surface emitting laser 20 according to the second embodiment.

### 16. Surface Emitting Laser According to Sixteenth Embodiment of Present Technology

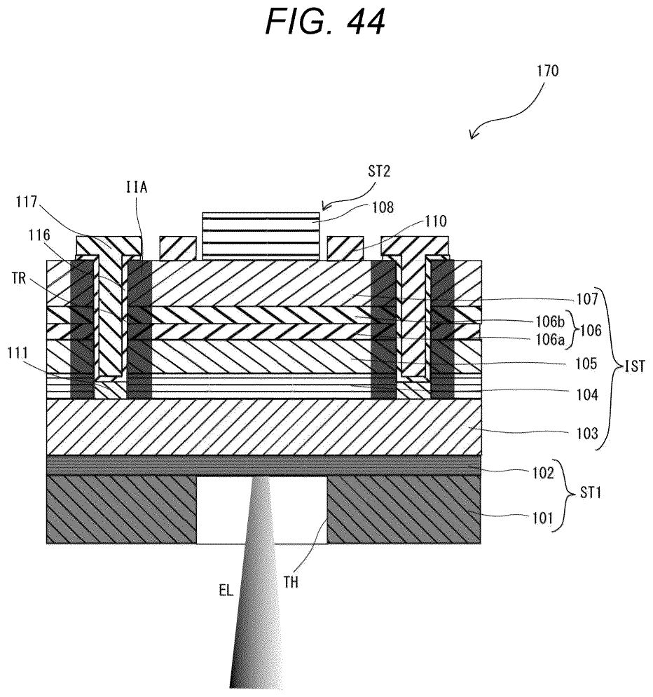

FIG. 44 is a cross-sectional view of a surface emitting laser 170 according to a sixteenth embodiment of the present technology. As illustrated in FIG. 44, the surface emitting laser 170 has a configuration substantially similar to that of the surface emitting laser 160 according to the fifteenth embodiment except that it is a backside emission type.

In the surface emitting laser 170, a through-hole TH is provided in the substrate 101 at a position corresponding to the light emitting unit. The surface emitting laser 170 includes a pad metal 116 having a portion in contact with the cathode electrode 111 and another portion provided on the side surface of the trench TR and the region of the upper surface of the third cladding layer 107 around the through-hole TH. The surface emitting laser 170 further includes a plating metal 117 having a portion provided on the pad metal 116 and another portion exposed on the third cladding layer 107.

The reflectivity of the second reflector 108 is set slightly higher than that of the first reflector 102.

Since the anode electrode 110 and the cathode electrode 111 are exposed on the third cladding layer 107, the surface emitting laser 170 is suitable for flip-chip (junction-down) mounting on a laser driver.

The surface emitting laser 170 can be manufactured by a method substantially similar to the manufacturing method of the surface emitting laser 160 according to the fifteenth embodiment except that the pad metal 116 and the plating metal 117 are formed in the trench TR, and the through-hole TH is formed in the substrate 101.

According to the surface emitting laser 170, it is possible to obtain effects similar to those of the surface emitting laser 10 according to the first embodiment, and it is possible to provide a backside emission type surface emitting laser that has a mesa-free Structure and is easily flip-chip mounted on a laser driver.

### 17. Surface Emitting Laser According to Seventeenth Embodiment of Present Technology

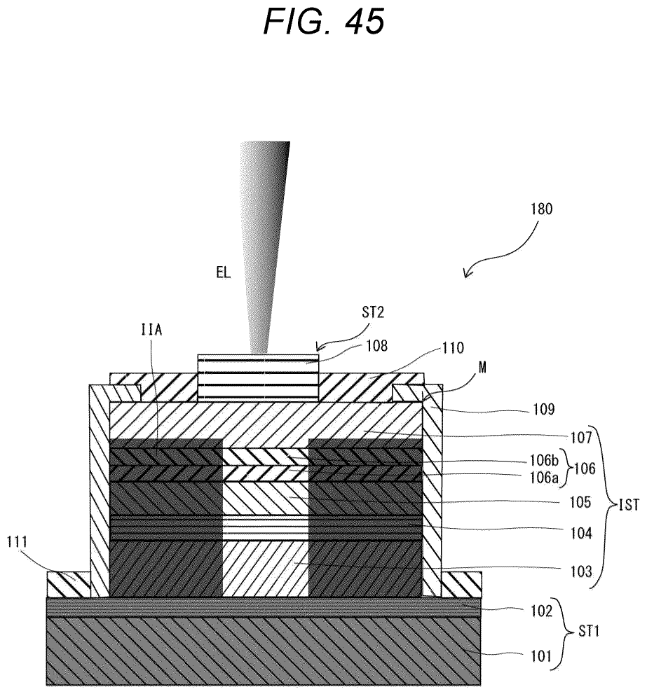

FIG. 45 is a cross-sectional view of a surface emitting laser 180 according to a seventeenth embodiment of the present technology. As illustrated in FIG. 45, the surface emitting laser 180 has a configuration substantially similar to that of the surface emitting laser 20 according to the second embodiment except that the bottom surface of the mesa M coincides with the upper surface of the first reflector 102 and the ion implantation region IIA is not provided at least above the third cladding layer 107.

In the surface emitting laser 180, the GaAs-based semiconductor multilayer film reflector as the first reflector 102 is doped with n-type doping, and the cathode electrode 111 is provided on the first reflector 102.

In the surface emitting laser 180, the ion implantation region IIA is provided over at least the first cladding layer 103, the active layer 104, the second cladding layer 105, and the tunnel junction layer 106.

The surface emitting laser 180 can be manufactured by a manufacturing method substantially similar to the manufacturing method of the surface emitting laser 20 according to the second embodiment except that the first cladding layer 103 is also etched at the time of forming the mesa M, the cathode electrode 111 is provided on the first reflector 102, and ion implantation is performed from the side corresponding to the first cladding layer 103.

According to the surface emitting laser 180, it is possible to obtain effects similar to those of the surface emitting laser 20 according to the second embodiment, and it is possible to provide a surface emitting laser with higher efficiency and higher output.

### 18. Modifications of Present Technology

The present technology is not limited to the embodiments described above, and various modifications can be made.

For example, the material of the substrate 101 is not limited to Ge, and may be any material as long as the material has a lattice constant greater than the lattice constant of GaAs and less than the lattice constant of AlAs.

For example, instead of the InP-based material, a GaN-based material (a material system lattice-matching with GaN) may be used for the intermediate structure IST.

In the surface emitting laser of each of the above embodiments, the conductivity types (p-type and n-type) of the first and second structures ST1 and ST2 may be interchanged. In this case, the Ge substrate as the substrate 101 may be undoped or doped with p-type doping. Examples of the p-type impurity doped in the Ge substrate include group III elements (for example, Ga). In a case where the first reflector 102 or the second reflector 108 is a p-type GaAs-based semiconductor multilayer film reflector, for example, Mg, C, Zn, or the like can be used as the dopant (p-type impurity).

Some of the configurations of the surface emitting lasers according to each of the above embodiments may be combined within a range in which they do not contradict each other.

In each of the embodiments described above, the material, conductivity type, thickness, width, length, shape, size, layout, and the like of each component constituting the surface emitting laser and the ranging device can be appropriately changed within a range functioning as the surface emitting laser or the ranging device.

### 19. Application Examples to Electronic Device

The technology according to the present disclosure (the present technology) can be applied to various products (electronic devices). For example, the technology according to the present disclosure may be realized as any type of moving body such as an automobile, an electric vehicle, a hybrid electric vehicle, a motorcycle, a bicycle, a personal mobility, an airplane, a drone, a ship, or a robot, or as an apparatus mounted on a low power consumption device (for example, a smartphone, a tablet, a mouse, or the like).

The surface emitting laser according to the present technology can also be applied as, for example, a light source of a device that forms or displays an image by laser light (for example, a laser printer, a laser copier, a projector, a head-mounted display, a head-up display, or the like).

### 20. Example in which Surface Emitting Laser is Applied to Distance Measuring Device

Hereinafter, application examples of the surface emitting laser according to each of the embodiments and modifications described above will be described.

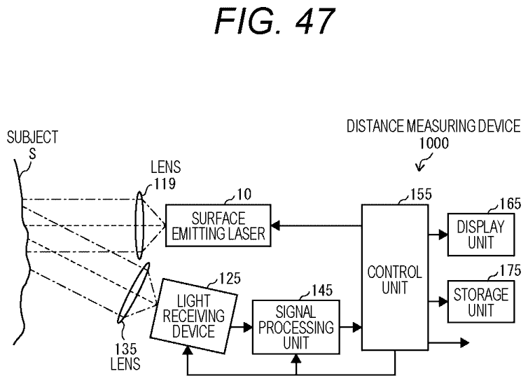

FIG. 47 illustrates an example of a schematic configuration of a distance measuring device 1000 including a surface emitting laser 10 as an example of an electronic device. The distance measuring device 1000 measures the distance to a subject S by a time of flight (TOF) method. The distance measuring device 1000 includes the surface emitting laser 10 as a light source. The distance measuring device 1000 includes, for example, a surface emitting laser 10, a light receiving device 125, lenses 119 and 135, a signal processing unit 145, a control unit 155, a display unit 165, and a storage unit 175.

The light receiving device 125 detects light reflected by the subject S. The lens 119 is a lens for collimating the light emitted from the surface emitting laser 10, and is a collimating lens. The lens 135 is a lens for condensing the light reflected by the subject S and guiding the light to the light receiving device 125, and is a condenser lens.

The signal processing unit 145 is a circuit for generating a signal corresponding to a difference between the signal input from the light receiving device 125 and the reference signal input from the control unit 155. The control unit 155 includes, for example, a time to digital converter (TDC). The reference signal may be a signal input from the control unit 155, or may be an output signal of a detection unit that directly detects the output of the surface emitting laser 10. The control unit 155 is, for example, a processor that controls the surface emitting laser 10, the light receiving device 125, the signal processing unit 145, the display unit 165, and the storage unit 175. The control unit 155 is a circuit that measures the distance to the subject S on the basis of the signal generated by the signal processing unit 145. The control unit 155 generates a video signal for displaying information regarding the distance to the subject S, and outputs the video signal to the display unit 165. The display unit 165 displays information regarding the distance to the subject S on the basis of the video signal input from the control unit 155. The control unit 155 stores information regarding the distance to the subject S in the storage unit 175.

In the present application example, instead of the surface emitting laser 10, any one of the surface emitting lasers 10, 20, 30-1, 30-2, 30-3, 40-1, 40-2, 40-3, 50, 60-1, 60-2, 60-3, 70, 80, 90, 120, 130, 140, 150, 160, 170, 180, and the ranging device 100 can be applied to the distance measuring device 1000.

### 21. Example in which Distance Measuring Device is Mounted on Moving Body

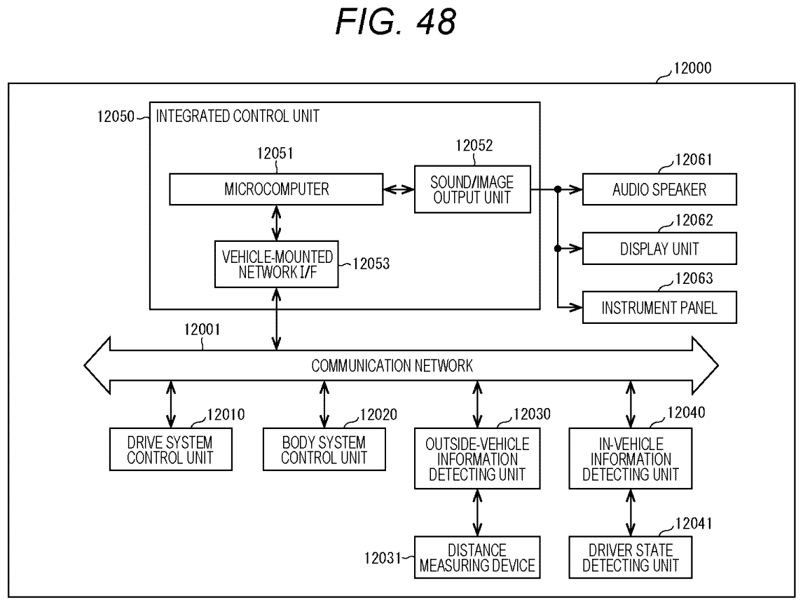

FIG. 48 is a block diagram depicting an example of schematic configuration of a vehicle control system as an example of a moving body control system to which the technology according to an embodiment of the present disclosure can be applied.

The vehicle control system 12000 includes multiple electronic control units connected to each other via a communication network 12001. In the example depicted in FIG. 48, the vehicle control system 12000 includes a drive system control unit 12010, a body system control unit 12020, an outside-vehicle information detecting unit 12030, an in-vehicle information detecting unit 12040, and an integrated control unit 12050. Furthermore, a microcomputer 12051, a sound/image output unit 12052, and a vehicle-mounted network interface (I/F) 12053 are illustrated as a functional configuration of the integrated control unit 12050.

The drive system control unit 12010 controls an operation of a device related to a drive system of a vehicle according to various programs. For example, the drive system control unit 12010 serves as a control device of a driving force generating device for generating driving force of the vehicle such as an internal combustion engine, a driving motor, or the like, a driving force transmitting mechanism for transmitting the driving force to wheels, a steering mechanism for adjusting a rudder angle of the vehicle, a braking device for generating braking force of the vehicle and the like.

The body system control unit 12020 controls operations of various devices mounted on a vehicle body according to the various programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives an input of the radio wave or signals and controls a door locking device, a power window device, the lights, and the like of the vehicle.

The outside-vehicle information detecting unit 12030 detects information about the outside of the vehicle including the vehicle control system 12000. For example, a distance measuring device 12031 is connected to the outside-vehicle information detecting unit 12030. The distance measuring device 12031 includes the distance measuring device 1000 described above. The outside-vehicle information detecting unit 12030 causes the distance measuring device 12031 to measure a distance to an object (subject S) outside the vehicle, and acquires distance data obtained by the measurement. The outside-vehicle information detecting unit 12030 may perform object detection processing of a person, a car, an obstacle, a sign, or the like on the basis of the obtained distance data.

The in-vehicle information detecting unit 12040 detects information about the inside of the vehicle. The in-vehicle information detecting unit 12040 is, for example, connected with a driver state detection unit 12041 that detects the state of a driver. The driver state detection unit 12041, for example, includes a camera that images the driver. On the basis of detection information input from the driver state detection unit 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the drive system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020 on the basis of the information about the outside of the vehicle, which is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output unit 12052 transmits an output signal of at least one of a sound and an image to an output device capable of visually or auditorily notifying information to an occupant of the vehicle or the outside of the vehicle. In the example of FIG. 48, an audio speaker 12061, a display unit 12062, and an instrument panel 12063 are illustrated as the output device. The display unit 12062 may, for example, include at least one of an on-board display and a head-up display.

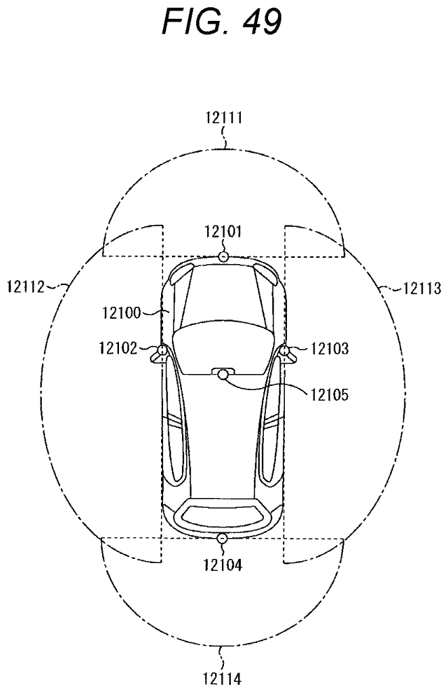

FIG. 49 is a view illustrating an example of an installation position of distance measuring device 12031.

In FIG. 49, a vehicle 12100 includes distance measuring devices 12101, 12102, 12103, 12104, and 12105 as the distance measuring device 12031.

For example, the distance measuring devices 12101, 12102, 12103, 12104, and 12105 are provided at positions such as a front nose, sideview mirrors, a rear bumper, a back door, an upper portion of a windshield in a vehicle interior, and the like of the vehicle 12100. The distance measuring device 12101 provided at the front nose and the distance measuring device 12105 provided at the upper portion of the windshield in the vehicle interior mainly acquire data of the front side of the vehicle 12100. The distance measuring devices 12102 and 12103 provided at the sideview mirrors mainly acquire data of the sides of the vehicle 12100. The distance measuring device 12104 provided at the rear bumper or the back door mainly acquires data of the rear side of the vehicle 12100. The data of the front side obtained by the distance measuring devices 12101 and 12105 is mainly used to detect a preceding vehicle, a pedestrian, an obstacle, a traffic light, a traffic sign, or the like.

Note that FIG. 49 illustrates an example of detection ranges of the distance measuring devices 12101 to 12104. A detection range 12111 indicates a detection range of the distance measuring device 12101 provided at the front nose, detection ranges 12112 and 12113 indicate detection ranges of the distance measuring devices 12102 and 12103 provided at the sideview mirrors, respectively, and a detection range 12114 indicates a detection range of the distance measuring device 12104 provided at the rear bumper or the back door.

For example, the microcomputer 12051 may obtain a distance to each three-dimensional object within the detection ranges 12111 to 12114 and a temporal change in the distance (relative speed with respect to the vehicle 12100) on the basis of the distance data obtained from the distance measuring devices 12101 to 12104, whereby particularly a nearest three-dimensional object present on a traveling path of the vehicle 12100, which travels in substantially the same direction as the vehicle 12100 at a predetermined speed (for example, greater than or equal to 0 km/h), may be extracted as a preceding vehicle. Further, the microcomputer 12051 can set a following distance to be maintained in front of a preceding vehicle in advance, and perform automatic brake control (including follow-up stop control), automatic acceleration control (including follow-up start control), or the like. In this way, it is possible to perform cooperative control for the purpose of, for example, automatic driving for autonomously traveling without depending on an operation of the driver.

For example, on the basis of the distance data obtained from the distance measuring devices 12101 to 12104, the microcomputer 12051 can classify three-dimensional object data regarding three-dimensional objects into two-wheeled vehicles, standard-sized vehicles, large-sized vehicles, pedestrians, and other three-dimensional objects such as utility poles, extract the three-dimensional object data, and use the three-dimensional object data for automatic avoidance of obstacles. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 can determine a collision risk indicating a risk of collision with each obstacle, and provide driving assistance for collision avoidance by outputting an alarm to the driver via the audio speaker 12061 or the display unit 12062, or by performing forced deceleration and avoidance steering via the drive system control unit 12010, when the collision risk is equal to or greater than a set value and there is a possibility of collision.

An example of the moving body control system to which the technology according to the present disclosure can be applied has been described above. The technology according to the present disclosure may be applied to the distance measuring device 12031 among the configurations described above.

Furthermore, the present technology may also adopt the following configurations.

(1) A surface emitting laser including
a resonator including:
a first structure including a substrate and a first reflector stacked on each other;
a second structure that includes a second reflector and is disposed on a side of the first structure corresponding to the first reflector; and
an intermediate structure that includes an active layer and is disposed between the first and second structures, in which
the substrate includes a material having a lattice constant that is greater than a lattice constant of GaAs and less than a lattice constant of AlAs, and
the first reflector and the intermediate structure include different material systems.

(2) The surface emitting laser according to (1), in which the first reflector includes a material system that lattice-matches with GaAs, and the intermediate structure includes a material system that lattice-matches with InP.

(3) The surface emitting laser according to (1) or (2), in which the substrate includes Ge.

(4) The surface emitting laser according to any one of (1) to (3), in which the first structure and the intermediate structure are bonded.

(5) The surface emitting laser according to (4), in which a bonding layer is formed between the first structure and the intermediate structure.

(6) The surface emitting laser according to any one of (1) to (5), in which the intermediate structure includes a tunnel junction layer stacked on the active layer, the intermediate structure includes a confinement portion configured to confine at least a current, and the confinement portion includes a high resistance region or an insulating region that is present in a peripheral portion of at least a part of the intermediate structure in a thickness direction.

(7) The surface emitting laser according to (6), in which the confinement portion includes an ion implantation region.

(8) The surface emitting laser according to (6) or (7), in which the confinement portion includes the high resistance region or the insulating region that is present around at least the tunnel junction layer.

(9) The surface emitting laser according to any one of (6) to (8), in which the tunnel junction layer has a mesa shape, and the confinement portion includes the high resistance region that is present around the tunnel junction layer.

(10) The surface emitting laser according to any one of (6) to (9), in which the confinement portion includes the insulating region that is present around the tunnel junction layer.

(11) The surface emitting laser according to any one of (6) to (10), in which the tunnel junction layer includes an InAlAs layer around which the insulating region is present.

(12) The surface emitting laser according to any one of (6) to (11), in which the insulating region includes an oxidized region.

(13) The surface emitting laser according to any one of (6) to (12), in which the insulating region includes a void.

(14) The surface emitting laser according to any one of (1) to (13), in which the active layer includes a quantum dot active layer.

(15) The surface emitting laser according to any one of (6) to (14), in which the confinement portion is loop-shaped, the substrate includes a through-hole at a position corresponding to a region surrounded by the confinement portion, and the surface emitting laser is configured to emit light to a back surface side of the substrate.

(16) The surface emitting laser according to any one of (6) to (15), in which the tunnel junction layer is disposed on an opposite side of the active layer from the substrate.

(17) The surface emitting laser according to any one of (6) to (16), in which the tunnel junction layer is disposed on a side of the active layer corresponding to the substrate.

(18) The surface emitting laser according to any one of (6) to (17), in which the intermediate structure includes multiple semiconductor structures stacked on one another, and each of the multiple semiconductor structures includes the active layer and the tunnel junction layer.

(19) The surface emitting laser according to any one of (6) to (18), in which the intermediate structure includes the multiple confinement portions provided in an in-plane direction.

(20) A ranging device including:
the surface emitting laser according to any one of (1) to (19); and
a light receiving element provided on a substrate of the surface emitting laser.

(21) The ranging device according to (20), in which the light receiving element includes a material including at least SiGe.

(22) The surface emitting laser according to any one of (1) to (21), in which the second reflector and the intermediate structure include different material systems.

(23) The surface emitting laser according to any one of (1) to (22), in which the first and second reflectors include a same material system.

(24) The surface emitting laser according to any one of (1) to (23), in which the second reflector includes a material system that lattice-matches with GaAs.

(25) The surface emitting laser according to any one of (1) to (24), in which the second structure and the intermediate structure are bonded.

(26) The surface emitting laser according to any one of (1) to (25), in which the second reflector includes a dielectric multilayer film reflector.

(27) A method for manufacturing a surface emitting laser, the method including the steps of:
generating a first laminate by stacking a first reflector including a first material system on a first substrate including a material having a lattice constant greater than a lattice constant of GaAs and less than a lattice constant of AlAs;
generating a second laminate by forming a stacked structure that includes a second material system and includes an active layer and a second reflector on a second substrate in this order;
removing at least the second substrate from the second laminate;
bonding a surface of the first laminate on a side corresponding to the first reflector and a surface of the second laminate on a side corresponding to the stacked Structure so as to face each other.

(28) A method for manufacturing a surface emitting laser, the method including the steps of:
generating a first laminate by stacking a first reflector including a first material system on a first substrate including a material having a lattice constant greater than a lattice constant of GaAs and less than a lattice constant of AlAs;
generating a joined body by bonding a surface of the first laminate on a side corresponding to the first reflector and one surface of the second substrate so as to face each other;
removing a part of the second substrate from the joined body; and
forming a stacked structure including a second material system and a second reflector on another portion of the second substrate of the joined body.

### REFERENCE SIGNS LIST

10, 20, 30-1, 30-2, 30-3, 40, 40-1, 40-2, 40-3, 50, 60-1, 60-2, 60-3, 70, 80, 90, 110, 120, 130, 140, 150, 160,
170, 180 Surface emitting laser
100 Ranging device
101 Substrate
102 First reflector
104 Active layer
106 Tunnel junction layer
106a2 Oxidized region (confinement portion)
106b2 Oxidized region (confinement portion)
107 Third cladding layer (confinement portion)
108 Second reflector
ST1 First structure
ST2 Second structure
IST Intermediate structure
R Resonator
ITA Ion implantation region (confinement portion)
V Void (confinement portion)

1. A surface emitting laser comprising
a resonator including:
a first structure including a substrate and a first reflector stacked on each other;
a second structure that includes a second reflector and is disposed on a side of the first structure corresponding to the first reflector; and
an intermediate structure that includes an active layer and is disposed between the first and second structures, wherein
the substrate includes a material having a lattice constant that is greater than a lattice constant of GaAs and less than a lattice constant of AlAs, and
the first reflector and the intermediate structure include different material systems.

2. The surface emitting laser according to claim 1, wherein
the first reflector includes a material system that lattice-matches with GaAs, and
the intermediate structure includes a material system that lattice-matches with InP.

3. The surface emitting laser according to claim 1, wherein the substrate includes Ge.

4. The surface emitting laser according to claim 1, wherein the first structure and the intermediate structure are bonded.

5. The surface emitting laser according to claim 4, wherein a bonding layer is formed between the first structure and the intermediate structure.

6. The surface emitting laser according to claim 1, wherein
the intermediate structure includes a tunnel junction layer stacked on the active layer,
the intermediate structure includes a confinement portion configured to confine at least a current, and
the confinement portion includes a high resistance region or an insulating region that is present in a peripheral portion of at least a part of the intermediate structure in a thickness direction.

7. The surface emitting laser according to claim 6, wherein the confinement portion includes an ion implantation region.

8. The surface emitting laser according to claim 6, wherein the confinement portion includes the high resistance region or the insulating region that is present around at least the tunnel junction layer.

9. The surface emitting laser according to claim 8, wherein
the tunnel junction layer has a mesa shape, and
the confinement portion includes the high resistance region that is present around the tunnel junction layer.

10. The surface emitting laser according to claim 8, wherein the confinement portion includes the insulating region that is present around the tunnel junction layer.

11. The surface emitting laser according to claim 8, wherein the tunnel junction layer includes an InAlAs layer around which the insulating region is present.

12. The surface emitting laser according to claim 10, wherein the insulating region includes an oxidized region.

13. The surface emitting laser according to claim 10, wherein the insulating region includes a void.

14. The surface emitting laser according to claim 1, wherein the active layer includes a quantum dot active layer.

15. The surface emitting laser according to claim 6, wherein
the confinement portion is loop-shaped,
the substrate includes a through-hole at a position corresponding to a region surrounded by the confinement portion, and
the surface emitting laser is configured to emit light to a back surface side of the substrate.

16. The surface emitting laser according to claim 6, wherein the tunnel junction layer is disposed on an opposite side of the active layer from the substrate.

17. The surface emitting laser according to claim 6, wherein the tunnel junction layer is disposed on a side of the active layer corresponding to the substrate.

18. The surface emitting laser according to claim 6, wherein
the intermediate structure includes multiple semiconductor structures stacked on one another, and
each of the multiple semiconductor structures includes the active layer and the tunnel junction layer.

19. The surface emitting laser according to claim 6, wherein the intermediate structure includes the multiple confinement portions provided in an in-plane direction.

20. A ranging device comprising:
the surface emitting laser according to claim 1; and
a light receiving element provided on a substrate of the surface emitting laser.
